(19) United States
(12) Patent Application Publication
(10) Pub. No.: US 2026/0314405 A1
(43) Pub. Date: Oct. 8, 2026

(54) SEMICONDUCTOR CHIP, CHIP STACKED STRUCTURE AND SEMICONDUCTOR PACKAGE INCLUDING THE SAME

(71) Applicant: Samsung Electronics Co., Ltd., Suwon-si (KR)

(72) Inventors: Jisoo KIM, Suwon-si (KR); Jeongeun HER, Suwon-si (KR); Sangbong LEE, Suwon-si (KR); Jaeho JEON, Suwon-si (KR); Hojun CHOI, Suwon-si (KR); Dong-Hwan HAN, Suwon-si (KR)

(21) Appl. No.: 19/329,850

(22) Filed: Sep. 16, 2025

(30) Foreign Application Priority Data
Apr. 7, 2025 (KR) 10-2025-0044656

(51) Int. Cl. H01L 23/373; H01L 23/48; H01L 23/522; H01L 25/065

(52) U.S. Cl. CPC H10W 40/25; H10W 20/20; H10W 20/42; H10W 90/00; H10W 72/07251; H10W 72/20; H10W 90/722; H10W 90/724

(57) ABSTRACT

According to some embodiments of the present disclosure, a semiconductor chip includes a device layer having a first surface and a second surface opposite to the first surface and a first wiring structure on the first surface of the device layer. The first wiring structure includes a first via layer having a first via, a first metal layer having a first wiring, the first metal layer being stacked on the first via layer in a first direction perpendicular to the first surface of the device layer, and a first heat-dissipation structure including a first heat-dissipation film having a first portion surrounding a bottom surface and a side surface of the first via. The first heat-dissipation structure includes a 2D material, and an upper surface of the first portion of the first heat-dissipation film contacts a lower surface of the first wiring.

### CROSS-REFERENCE TO RELATED APPLICATION(S)

This application claims benefit of priority under 35 U.S.C. § 119 to Korean Patent Application No. 10-2025-0044656, filed on Apr. 7, 2025, in the Korean Intellectual Property Office, the disclosure of which is incorporated herein by reference in its entirety.

### TECHNICAL FIELD

The present disclosure relates to a semiconductor chip, a chip stacked structure, and a semiconductor package including the same.

### BACKGROUND

As electronic devices become lighter and higher in performance, development of smaller and higher-performance semiconductor packages is also required in the field of semiconductor packaging. Semiconductor packages in which a plurality of semiconductor chips are vertically stacked have been continuously researched and developed in order to achieve miniaturization, weight reduction, high performance, and high reliability of the semiconductor package.

When a plurality of semiconductor chips are stacked, power density increases, and heat may be generated when power and signals are exchanged among the stacked semiconductor chips. Because the generated heat may raise the temperature of the plurality of semiconductor chips or the semiconductor package, the heat needs to be dissipated to the outside.

An object of the present disclosure is to provide a semiconductor chip, a chip stacked structure, and a semiconductor package including the same, whose heat-dissipation performance is improved.

Another object of the present disclosure is to provide a semiconductor chip, a chip stacked structure, and a semiconductor package including the same, whose electrical performance and electrical reliability are improved.

### SUMMARY

According to some embodiments of the present disclosure, a semiconductor chip includes a device layer having a first surface and a second surface opposite to the first surface, and a first wiring structure on the first surface of the device layer. The first wiring structure includes a first via layer including a first via, a first metal layer including a first wiring, the first metal layer being stacked on the first via layer in a first direction perpendicular to the first surface of the device layer, and a first heat-dissipation structure including a first heat-dissipation film including a first portion surrounding a bottom surface and a side surface of the first via, and the first heat-dissipation structure may be formed of a two-dimensional (2D) material. An upper surface of the first portion of the first heat-dissipation film may contact a lower surface of the first wiring.

According to some embodiments of the present disclosure, a chip stacked structure includes a first semiconductor chip including a first substrate, a first device layer on the first substrate, and a first front side wiring structure on a front surface of the first device layer, a second semiconductor chip including a second substrate, a second device layer on the second substrate, and a second front side wiring structure on a front surface of the second device layer, the second semiconductor chip being stacked on the first semiconductor chip, a through electrode penetrating at least a portion of the first semiconductor chip, and a through heat-dissipation film surrounding at least a portion of the through electrode. The first front side wiring structure includes a first front side via layer including a first front side via, the first front side via layer being disposed on the first device layer, a first front side metal layer including a first front side wiring, the first front side metal layer being disposed on the first front side via layer, and a first front side heat-dissipation structure including a first portion surrounding a bottom surface and a side surface of the first front side via. The second front side wiring structure includes a second front side via layer including a second front side via, the second front side via layer being disposed on the second device layer, a second front side metal layer including a second front side wiring, the second front side metal layer being disposed on the second front side via layer, and a second front side heat-dissipation structure including a first portion surrounding a bottom surface and a side surface of the second front side via.

According to some embodiments of the present disclosure, a semiconductor package includes a package substrate and a chip stacked structure disposed on the package substrate. The chip stacked structure includes a first semiconductor chip including a first device layer and a first front side wiring structure on the first device layer, a second semiconductor chip including a second device layer and a second front side wiring structure on the second device layer and stacked on the first semiconductor chip, a through electrode penetrating at least a portion of the first semiconductor chip, and a through heat-dissipation film surrounding at least a portion of the through electrode. The first front side wiring structure includes a first front side via layer including a first front side via, a first front side metal layer including a first front side wiring, the first front side metal layer being disposed on the first front side via layer, and a first front side heat-dissipation structure including a first portion surrounding a bottom surface and a side surface of the first front side via, and the second front side wiring structure includes a second front side via layer including a second front side via, a second front side metal layer including a second front side wiring, the second front side metal layer being disposed on the second front side via layer, and a second front side heat-dissipation structure including a first portion surrounding a bottom surface and a side surface of the second front side via. The through heat-dissipation film, the first front side heat-dissipation structure, and the second front side heat-dissipation structure may include a 2D material.

According to some embodiments of the present disclosure, a method of manufacturing a semiconductor chip includes forming a device layer on a substrate and forming a front side wiring structure on the device layer. The forming of the front side wiring structure may include forming a first front side via layer, forming a first front side metal layer on the first front side via layer, and forming a first front side heat-dissipation film in the first front side via layer and the first front side metal layer.

According to the above manufacturing method, forming the first front side via layer may include forming a first interlayer insulating film on the device layer, forming a first via hole in the first interlayer insulating film, and filling a conductive material in the first via hole to form the first via.

The above manufacturing method may further include forming a heat-dissipation insulation film on a part of the first front side heat-dissipation film.

According to the above manufacturing method, the first front side heat-dissipation film may include graphene, and the heat-dissipation insulation film may include graphene oxide.

According to the above manufacturing method, the forming of the heat-dissipation insulation film may be performed by an oxidation process.

The above manufacturing method may further include, after forming the front side wiring structure, forming a back side wiring structure. Forming the back side wiring structure may include attaching a support substrate on the front side wiring structure, removing the substrate, forming a first back side via layer on the device layer, forming a first back side metal layer on the first back side via layer, and forming a first back side heat-dissipation film in the first back side via layer and the first back side metal layer.

The above manufacturing method may further include, after forming the back side wiring structure, forming a through electrode. Forming the through electrode may include forming a trench penetrating the support substrate, the front side wiring structure, and the device layer, forming a through heat-dissipation film in the trench, and filling a conductive material on the through heat-dissipation film.

The above manufacturing method may further include forming a surface heat-DISSIPATION film on the support substrate.

According to some embodiments of the present disclosure, heat-dissipation performance of the semiconductor chip, the chip stacked structure, and the semiconductor package including the same may be improved.

According to some embodiments of the present disclosure, electrical performance and electrical reliability of the semiconductor chip, the chip stacked structure, and the semiconductor package including the same may be improved.

### BRIEF DESCRIPTION OF THE DRAWINGS

FIG. 1 is a cross-sectional view illustrating a semiconductor package according to some example embodiments of the present disclosure.

FIG. 2 is a cross-sectional view illustrating some components of a semiconductor chip according to some example embodiments of the present disclosure.

FIG. 3 is a cross-sectional view illustrating some components of a semiconductor chip according to some example embodiments of the present disclosure.

FIG. 4 is a cross-sectional view illustrating some components of a semiconductor chip according to some example embodiments of the present disclosure.

FIG. 5 is a cross-sectional view illustrating some components of a semiconductor chip according to some example embodiments of the present disclosure.

FIG. 6 is a cross-sectional view illustrating some components of a semiconductor chip according to some example embodiments of the present disclosure.

FIG. 7 is a cross-sectional view illustrating some components of a semiconductor chip according to some example embodiments of the present disclosure.

FIGS. 8-11 are cross-sectional views illustrating chip stacked structures according to some example embodiments of the present disclosure.

FIGS. 12-21 are cross-sectional views illustrating methods of manufacturing a semiconductor chip and a chip stacked structure according to some example embodiments of the present disclosure.

### DETAILED DESCRIPTION

With reference to the drawings, a semiconductor chip, a chip stacked structure, and a semiconductor package including the same according to some embodiments of the present disclosure are described in detail below. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be understood that, although the terms first and/or primary, second and/or secondary, third and/or tertiary, etc. may be used herein to describe various elements, components, regions, layers and/or sections, these elements, components, regions, layers and/or sections should not be limited by these terms. Such terms may include, for example and without limitation, “first,” “primary first,” “secondary first,” “second,” “primary second,” “secondary second,” etc. Unless the context indicates otherwise, these terms are only used to distinguish one element, component, region, layer, or section from another element, component, region, layer or section, for example as a naming convention. Thus, a first and/or primary element, component, region, layer or section discussed below in one section of the specification could be termed a second and/or secondary element, component, region, layer or section in another section of the specification or in the claims without departing from the teachings of the present invention. In addition, in certain cases, even if a term is not described using first and/or primary, second and/or secondary, etc. in the specification, it may still be referred to as first and/or primary, second and/or secondary in a claim in order to distinguish different claimed elements from each other.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

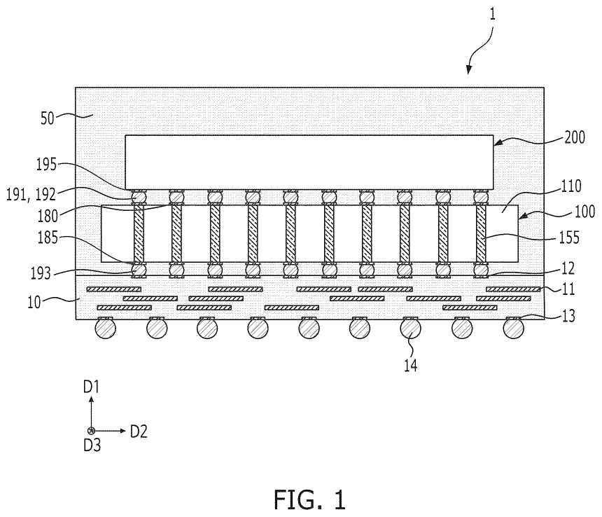

FIG. 1 is a cross-sectional view illustrating a semiconductor package according to some example embodiments of the present disclosure.

Referring to FIG. 1, a semiconductor package 1 according to some embodiments of the present disclosure may include a package substrate 10, a first semiconductor chip 100, a second semiconductor chip 200, first and second connection terminals 191 and 192, lower terminals 193, and a molding layer 50.

The package substrate 10 may be a printed circuit board PCB, a ceramic substrate, a package-manufacturing wafer, an interposer, or a redistribution layer. In some embodiments, the printed circuit board may be a multilayer printed circuit board having a substrate base in which a plurality of base layers are stacked. In some embodiments, each of the plurality of base layers constituting the substrate base may be formed of at least one material selected from phenolic resin, epoxy resin, and polyimide. For example, each of the plurality of base layers constituting the substrate base may be formed of or include at least one material selected from Frame Retardant 4 (FR-4), tetrafunctional epoxy, polyphenylene ether, epoxy/polyphenylene oxide, BT (Bismaleimide Triazine) resin, Thermount, cyanate ester, polyimide, and liquid-crystal polymer.

The package substrate 10 may include a wiring pattern 11, upper pads 12, and lower pads 13. The wiring pattern 11 may be disposed on an upper surface and a lower surface of each of the plurality of base layers. The wiring pattern 11 may be, for example, formed of electrolytically deposited copper foil, rolled-annealed copper foil, stainless-steel foil, aluminum foil, ultra-thin copper foil, sputtered copper, copper alloy, and the like. In some embodiments, conductive vias (not shown) that connect the wiring patterns 11 to each other may electrically connect the wiring patterns 11 to each other. For example, each of the conductive vias may contact respective upper and lower surfaces of wiring patterns 11 at different layers. The conductive vias may be formed to penetrate at least one of the plurality of base layers. In some embodiments, each conductive via may be formed of copper, nickel, stainless steel, or beryllium copper.

The upper pads 12 may be disposed on an upper surface of the package substrate 10, and the lower pads 13 may be disposed on a lower surface of the package substrate 10. For example, upper surfaces of the upper pads 12 may be coplanar with an upper surface of the package substrate 10, and lower surfaces of the lower pads 13 may be coplanar with a lower surface of the package substrate 10. Each of the upper pads 12 and the lower pads 13 may be provided in plural numbers. Lower terminals 193 may be disposed on the upper pads 12. For example, each lower terminal 193 may contact the upper surface of a corresponding one of the upper pads 12. The first semiconductor chip 100 and the package substrate 10 may be electrically connected through the upper pads 12 and the lower terminals 193.

A plurality of external terminals 14 may be disposed on the plurality of lower pads 13. For example, each external terminal 14 may contact the lower surface of a corresponding one of the plurality of lower pads 13. The semiconductor package 1 may be mounted on a system board through the plurality of external terminals 14 and the plurality of lower pads 13. For example, the plurality of external terminals 14 may be electrically connected to pads of the system board.

The first semiconductor chip 100 may be mounted on the package substrate 10. An upper surface of the first semiconductor chip 100 denotes a surface facing the second semiconductor chip 200, and a lower surface of the first semiconductor chip 100 denotes a surface facing the package substrate 10. In some embodiments, the upper surface of the first semiconductor chip 100 may be a back surface on which a back side wiring layer is formed. In another embodiment, the upper surface of the first semiconductor chip 100 may be a front surface on which the device layer and the front side wiring layer are formed.

The first semiconductor chip 100 may include a first substrate 110, upper pads 180, and lower pads 185, and through electrodes 155.

The first substrate 110 may include a semiconductor element such as silicon or germanium or may include a compound semiconductor such as silicon carbide (SiC), gallium arsenide (GaAs), indium arsenide (InAs), or indium phosphide (InP). The first substrate 110 may have a silicon-on-insulator (SOI) structure. The first substrate 110 may include a conductive region, for example, a well doped with an impurity or a structure doped with an impurity. The first substrate 110 may include various device isolation structures such as shallow trench isolation (STI).

The upper pads 180 may be disposed on the upper surface of the first semiconductor chip 100. For example, the upper pads 180 may contact the upper surface of the first semiconductor chip 100 and upper surfaces of the through electrodes 155. The upper pads 180 may be provided in plural numbers. Each upper pad 180 may be formed of or include at least one selected from aluminum (Al), copper (Cu), nickel (Ni), tungsten (W), platinum (Pt), and gold (Au).

The lower pads 185 may be disposed on the lower surface of the first semiconductor chip 100. For example, the lower pads 185 may contact the lower surface of the first semiconductor chip 100 and lower surfaces of the through electrodes 155. The lower pads 185 may be provided in plural numbers. Each lower pad 185 may be formed of or include at least one selected from aluminum (Al), copper (Cu), nickel (Ni), tungsten (W), platinum (Pt), and gold (Au).

The first and second connection terminals 191 and 192 may be disposed on the upper pads 180 of the first semiconductor chip 100. The second semiconductor chip 200 and the first semiconductor chip 100 may be electrically connected through the upper pads 180, the first and second connection terminals 191 and 192, and the lower pads 195, which are provided on a lower surface of the second semiconductor chip 200. Lower terminals 193 may be disposed on the lower pads 185 on the lower surface of the first semiconductor chip 100. For example, each lower terminal 193 may contact a corresponding one of the lower pads 185 of the first semiconductor chip 100. Each of the first and second connection terminals 191 and 192 and the lower terminals 193 may be formed of or include tin (Sn), indium (In), bismuth (Bi), antimony (Sb), copper (Cu), silver (Ag), zinc (Zn), lead (Pb), and/or an alloy thereof. The alloy may be formed of or include, for example, Sn-Pb, Sn-Ag, Sn-Au, Sn-Cu, Sn-Bi, Sn-Zn, Sn-Ag-Cu, Sn-Ag-Bi, Sn-Ag-Zn, Sn-Cu-Bi, Sn-Cu-Zn, and Sn-Bi-Zn.

The through electrodes 155 may extend in a first direction D1 perpendicular to the upper surface of the first semiconductor chip 100. The first direction D1 may correspond to a vertical direction. The through electrodes 155 may be located inside the first semiconductor chip 100 and may be arranged in a second direction D2 and a third direction D3 that are horizontal directions perpendicular to the first direction D1. The through electrodes 155 may penetrate the first substrate 110 in the first direction D1, penetrating between the upper surface and the lower surface of the first substrate 110. The through electrodes 155 may provide an electrical path connecting the upper pads 180 and the lower pads 185.

Each through electrode 155 may include a core metal layer and a barrier film surrounding the core metal layer. The core metal layer be formed of or may include a metal material such as tungsten (W), titanium (Ti), aluminum (Al), or copper (Cu), and may be formed by a plating process, physical vapor deposition (PVD), or chemical vapor deposition (CVD). The barrier film may be formed of or include a 2D material and may be formed of or include titanium (Ti), titanium nitride (TiN), tantalum (Ta), or tantalum nitride (TaN) and may be formed by plating, PVD, or CVD. In some embodiments, a side surface insulating film including an insulating material such as silicon oxide, silicon nitride, or silicon oxynitride may be formed between a side surface of the through electrode 155 and the first substrate 110.

The first semiconductor chip 100 may be, for example, a buffer chip that includes a plurality of logic devices and/or memory devices in the device layer. The first semiconductor chip 100 may transfer signals received from the second semiconductor chip 200 stacked thereon to the outside and may transfer signals and power received from the outside to the second semiconductor chip 200. Although the first semiconductor chip 100 may perform both logic and memory functions through logic devices and memory devices, the first semiconductor chip 100 may include only logic devices. In some embodiments, the first semiconductor chip 100 may include volatile memory devices such as DRAM and SRAM or non-volatile memory devices such as flash memory.

The second semiconductor chip 200 may be disposed on the upper surface of the first semiconductor chip 100 and may be stacked in the first direction D1 which is a direction perpendicular to the upper surface of the first semiconductor chip 100. In some embodiments, additional semiconductor chips may be further stacked in the first direction D1 on the second semiconductor chip 200.

The second semiconductor chip 200 may be configured as a memory chip or memory devices that store and/or output data based on address commands and control commands received. For example, the second semiconductor chip 200 may include volatile memory devices such as DRAM and SRAM or non-volatile memory devices such as PRAM, MRAM, FeRAM, or RRAM. In some embodiments, the second semiconductor chip 200 may be provided as a plurality of second semiconductor chips stacked in the first direction D1 on the first semiconductor chip 100.

The molding layer 50 may surround the first semiconductor chip 100 and the second semiconductor chip 200 on the package substrate 10. For example, the molding layer 50 may cover front surfaces, side surfaces, and back surfaces of the first semiconductor chip 100 and the second semiconductor chip 200. In some embodiments, the molding layer 50 may cover portions of the lower surfaces of the first semiconductor chip 100 and the second semiconductor chip 200. The molding layer 50 may include an insulating material such as a thermosetting resin like epoxy resin or a thermoplastic resin like polyimide. The molding layer 50 may include a resin including a reinforcing material such as an inorganic filler, e.g., ABF, FR-4, or BT resin. Further, the molding layer 50 may include a molding material such as EMC or a photosensitive material such as PIE (Photo Imageable Encapsulant).

The molding layer 50 may surround the first and second connection terminals 191 and 192 disposed between the first semiconductor chip 100 and the second semiconductor chip 200. The molding layer 50 may surround the lower terminals 193 disposed on the lower surface of the first semiconductor chip 100.

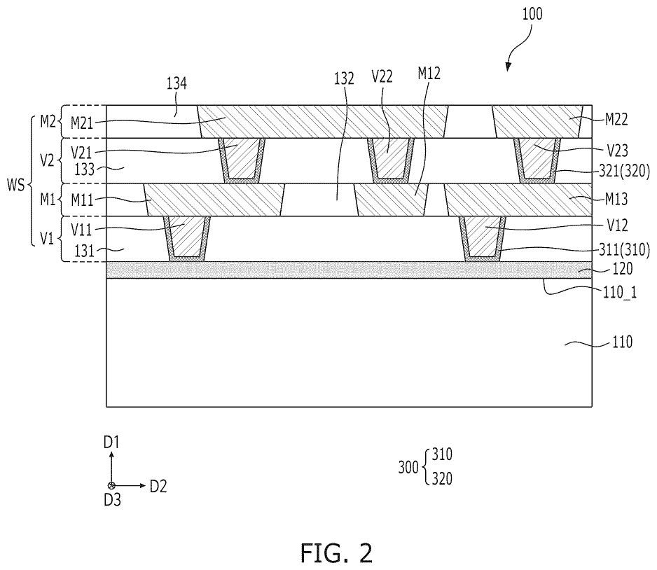

FIG. 2 is a cross-sectional view illustrating some components of a semiconductor chip according to some example embodiments of the present disclosure. In example embodiments, the semiconductor chip 100 of FIG. 2 may correspond to a portion of the semiconductor chip 100 of FIG. 1.

Referring to FIG. 2, a semiconductor chip 100 according to some embodiments of the present disclosure may include a substrate 110, a device layer 120, and a wiring structure WS.

The device layer 120 may be formed on the substrate 110. The device layer 120 may be disposed on a first surface 110_1 of the substrate 110, which may be referred to as a front surface of the substrate 110.

The device layer 120 may include various types of devices. For example, the device layer 120 may include field-effect transistors such as planar FET, FinFET, or GAAFET, memory devices such as flash memory, DRAM, SRAM, EEPROM, PRAM, MRAM, FeRAM, and RRAM, logic devices such as AND, OR, and NOT gates, system LSI, CIS, MEMS, and other active and/or passive devices.

In some embodiments, the device layer 120 may further include contact structures disposed on the devices. The contact structures may connect the devices to the wiring structure WS.

The wiring structure WS may be disposed on the device layer 120 and may be connected to the contact structures of the device layer 120. The wiring structure WS may be electrically connected to the device layer 120. The wiring structure WS may provide at least one of a signal line and/or a power line for the various devices in the device layer 120.

The wiring structure WS may include a first via layer V1, a first metal layer M1, a second via layer V2, a second metal layer M2, and a heat-dissipation structure 300. The first via layer V1, the first metal layer M1, the second via layer V2, and the second metal layer M2 may be sequentially stacked on the device layer 120, with the first via layer V1 positioned at the lowest part of the wiring structure WS. For example, the first via layer V1 may be positioned closest to the substrate 110 of the first via layer V1, the first metal layer M1, the second via layer V2, and the second metal layer M2. The numbers of layers and their arrangement in the wiring structure WS are merely illustrative, and the wiring structure WS may include more than the illustrated numbers or may include only a single via layer and a single metal layer.

The first via layer V1 may include a first-first via V11, a first-second via V12, and a first interlayer insulating film 131. This is merely illustrative, and the first via layer V1 may include three or more vias. The vias provided in the first via layer V1 may be referred to collectively as the first vias V11 and V12.

The first-first via V11 and the first-second via V12 may be disposed in the first interlayer insulating film 131. For example, the first-first via V11 and the first-second via V12 may be disposed on contact structures of the device layer 120. The first-first via V11 and the first-second via V12 may be electrically connected to the first metal layer M1. Although depicted as single-layer structures, the first-first via V11 and the first-second via V12 may have multilayer structures.

Widths of the first-first via V11 and the first-second via V12 may decrease toward the device layer 120. That is, the widths of the first-first via V11 and the first-second via V12 may increase as being farther away from the substrate 110. For example, the widths of the first-first via V11 and the first-second via V12 may be defined with reference to the second direction D2.

A first portion 311 of the first heat-dissipation film 310 may surround side surfaces of the first-first via V11 and the first-second via V12. For example, the first portion 311 of the first heat-dissipation film 310 may contact side surfaces of the first-first via V11 and the first-second via V12. In example embodiments, upper surfaces of the first-first via V11, the first-second via V12, and the first portion 311 of the first heat-dissipation film 310 may be coplanar with each other. In some embodiments, the upper surfaces of the first-first via V11, the first-second via V12, and the first portion 311 of the first heat-dissipation film 310 may be coplanar with an upper surfaces of the first interlayer insulating film 131. Lower surfaces of the first portion 311 of the first heat-dissipation film 310 may be coplanar with a lower surface of the first interlayer insulating film 131. Lower surfaces of the first portions 311 of the first heat-dissipation film 310 may contact an upper top surface of the device layer 120.

The first metal layer M1 may include a first-first wiring M11, a first-second wiring M12, a first-third wiring M13, and a second interlayer insulating film 132. This is merely illustrative, and the first metal layer M1 may include four or more wirings. The wirings provided in the first metal layer M1 may be referred to collectively as the first wirings M11, M12, and M13.

The first-first wiring M11, the first-second wiring M12, and the first-third wiring M13 may be disposed in the second interlayer insulating film 132. For example, the first-first wiring M11 may be disposed on the first-first via V11 and a first portion 311 of a first heat-dissipation film 310 surrounding the first-first via V11, and the first-third wiring M13 may be disposed on the first-second via V12 and a first portion 311 of the first heat-dissipation film 310 surrounding the first-second via V12. The first-first wiring M11, the first-second wiring M12, and the first-third wiring M13 may be electrically connected to the first via layer V1. For example, the first-first wiring M11, the first-second wiring M12, and the first-third wiring M13 may contact upper surfaces of the first via layer V1 and the first portion 311 of the first heat-dissipation film 310. Upper surfaces of the first-first wiring M11, the first-second wiring M12, the first-third wiring M13 may be coplanar with an upper surface of the first heat-dissipation film 310, and lower surfaces of the first-first wiring M11, the first-second wiring M12, and the first-third wiring M13 may be coplanar with a lower surface of the first heat-dissipation film 310. Although depicted as single-layer structures, the first-first wiring M11, the first-second wiring M12, and the first-third wiring M13 may have multilayer structures.

Widths of each of the first-first wiring M11, the first-second wiring M12, and the first-third wiring M13 may decrease toward the first via layer V1. That is, the widths of each of the first-first wiring M11, the first-second wiring M12, and the first-third wiring M13 may increase as being farther away from the substrate 110. For example, the widths of each of the first-first wiring M11, the first-second wiring M12, and the first-third wiring M13 may be defined with reference to the second direction D2.

The first vias V11 and V12 in the first via layer V1 and the first wirings M11, M12, and M13 in the first metal layer M1 may be formed by a damascene process. In some embodiments, at least some of the first vias V11 and V12 and the first wirings M11, M12, and M13 may be formed by a subtractive process.

The second via layer V2 may include a second-first via V21, a second-second via V22, a second-third via V23, and a third interlayer insulating film 133. This is merely illustrative, and the second via layer V2 may include four or more vias. The vias provided in the second via layer V2 may be referred to collectively as the second vias V21, V22, and V23.

The second-first via V21, the second-second via V22, and the second-third via V23 may be disposed in the third interlayer insulating film 133. For example, the second-first via V21, the second-second via V22, and the second-third via V23 may be disposed on the wirings M11, M12, and M13 of the first metal layer M1 and may electrically connect the first metal layer M1 and the second metal layer M2. Although depicted as single-layer structures, the second-first via V21, the second-second via V22, and the second-third via V23 may have multilayer structures.

Widths of the second-first via V21, the second-second via V22, and the second-third via V23 may decrease toward the first metal layer M1. That is, the widths of the second-first via V21, the second-second via V22, and the second-third via V23 may increase as being farther away from the substrate 110. For example, the widths of the second-first via V21, the second-second via V22, and the second-third via V23 may be defined with reference to the second direction D2.

A first portion 321 of the second heat-dissipation film 320 may surround side surfaces of the second-first via V21, the second-second via V22, and the second-third via V23. For example, the first portion 321 of the second heat-dissipation film 320 may contact side surfaces of the second-first via V21, the second-second via V22, and the second-third via V23. In example embodiments, upper surfaces of the second-first via V21, the second-second via V22, the second-third via V23, and the first portion 321 of the second heat-dissipation film 320 may be coplanar with each other. In some embodiments, upper surfaces of the second-first via V21, the second-second via V22, the second-third via V23, and the first portion 321 of the second heat-dissipation film 320 may be coplanar with an upper surface of the third interlayer insulating film 133. Lower surfaces of the first portion 321 of the second heat-dissipation film 320 may be coplanar with a lower surface of the third interlayer insulating film 133. Lower surfaces of the first portions 321 of the second heat-dissipation film 320 may contact upper surfaces of the first-first wiring M11, the first-second wiring M12, and the first-third wiring M13.

The metal layer M2 may include a second-first wiring M21, a second-second wiring M22, and a fourth interlayer insulating film 134. This is merely illustrative, and the second metal layer M2 may include three or more wirings. The wirings provided in the second metal layer M2 may be referred to collectively as the second wirings M21 and M22.

The second-first wiring M21 and the second-second wiring M22 may be disposed in the fourth interlayer insulating film 134. In example embodiments, upper surfaces of the second-first wiring M21, the second-second wiring M22, and the fourth interlayer insulating film 134 may be coplanar with each other, and lower surfaces of the second-first wiring M21, the second-second wiring M22, and the fourth interlayer insulating film 134 may be coplanar each other. For example, the second-first wiring M21 may be disposed on the second-first via V21 and a first portion 321 of a second heat-dissipation film 320 surrounding the second-first via V21 and on the second-second via V22 and a first portion 321 of the second heat-dissipation film 320 surrounding the second-second via V22. For example, the second-first wiring M21 may contact upper surfaces of the second-first via V21 and the first portion 321 of the second heat-dissipation film 320 surrounding the second-first via V21 and upper surfaces of the second-second via V22 and the first portion 321 of the second heat-dissipation film 320 surrounding the second-second via V22. The second-second wiring M22 may be electrically connected to the second-third via V23. For example, the second-second wiring M22 may be disposed on the second-third via V23 and a first portion 321 of the second heat-dissipation film 320 surrounding the second-third via V23. For example, the second-second wiring M22 may contact upper surfaces of the second-third via V23 and the first portion 321 of the second heat-dissipation film 320 surrounding the second-third via V23. Although depicted as single-layer structures, the second-first wiring M21 and the second-second wiring M22 may have multilayer structures.

Widths of the second-first wiring M21 and the second-second wiring M22 may decrease toward the second via layer V2. That is, the width of each of the second-first wiring M21 and the second-second wiring M22 may increase as being farther away from the substrate 110. For example, the widths of the second-first wiring M21 and the second-second wiring M22 may be defined with reference to the second direction D2.

The second vias V21, V22, and V23 in the second via layer V2 and the second wirings M21 and M22 in the second metal layer M2 may be formed by a single-damascene process. In some embodiments, at least some of the second vias V21, V22, and V23 and the second wirings M21 and M22 may be formed by a subtractive or a semi-damascene process.

The heat-dissipation structure 300 may include a first heat-dissipation film 310 and a second heat-dissipation film 320. The heat-dissipation structure 300 may be disposed in the first via layer V1 and the second via layer V2.

The first heat-dissipation film 310 may be provided in the first via layer V1, and the second heat-dissipation film 320 may be provided in the second via layer V2. The first heat-dissipation film 310 may include a first portion 311 surrounding at least one of a bottom surface and a side surface of at least one of the first vias V11 and V12. For example, the first portion 311 of the first heat-dissipation film 310 may contact the lower surface and the side surface of the first vias V11 and V12. The second heat-dissipation film 320 may include a first portion 321 surrounding at least one of a bottom surface and a side surface of at least one of the second vias V21, V22, and V23. For example, the first portion 321 of the second heat-dissipation film 320 may contact the lower surface and the side surface of the second vias V21, V22, and V23. For convenience of description, the first portion 311 of the first heat-dissipation film 310 is described as surrounding the bottom surface and the side surface of each of the first vias V11 and V12, and the first portion 321 of the second heat-dissipation film 320 is described as surrounding the bottom surface and the side surface of each of the second vias V21, V22, and V23. For example, in the embodiment of FIG. 2, the first portion 311 of the first heat-dissipation film 310 contacts the bottom and side surfaces of each of the first vias V11 and V12, and the first portion 321 of the second heat-dissipation film 320 contacts the bottom and side surfaces of each of the second vias V21, V22, and V23.

The first portion 311 of the first heat-dissipation film 310 may have a cup shape surrounding the bottom surface and the side surface of each of the first-first via V11 and the first-second via V12. In some embodiments, the first portion 311 of the first heat-dissipation film 310 may not be disposed on the bottom surfaces of the first-first via V11 and the first-second via V12. In such embodiments, the lower surfaces of the first-first via V11 and the first-second via V12 may be coplanar with the lower surface of the first interlayer insulating film 131.

The first portion 321 of the second heat-dissipation film 320 may have a cup shape surrounding the bottom surface and the side surface of each of the second-first via V21, the second-second via V22, and the second-third via V23. In some embodiments, the first portion 321 of the second heat-dissipation film 320 may not be disposed on the bottom surfaces of the second-first via V21, the second-second via V22, and the second-third via V23.

The heat-dissipation structure 300 may include a material having high thermal conductivity. For example, the heat-dissipation structure 300, that is, the first heat-dissipation film 310 and the second heat-dissipation film 320, may be formed of or include a 2D material such as graphene, diamond-like carbon (DLC), hexagonal boron nitride (hBN), or a transition-metal dichalcogenide (TMD). For example, the TMD may include at least one of MoS₂, WS₂, MoSe₂, WSe₂, HfS₂, and ZrS₂.

The first portion 311 of the first heat-dissipation film 310 may be a part of a path for dissipating heat generated inside the semiconductor chip 100. For example, the first portion 311 of the first heat-dissipation film 310 may be a part of a path for dissipating heat generated in the first vias V11 and V12 and the first wirings M11, M12, and M13. Likewise, the first portion 321 of the second heat-dissipation film 320 may be a part of a path for dissipating heat generated inside the semiconductor chip 100. For example, the first portion 321 of the second heat-dissipation film 320 may be a part of a path for dissipating heat generated in the second vias V21, V22, and V23 and the second wirings M21 and M22.

The heat-dissipation structure 300 may include a material having high electrical conductivity. For example, the first portion 311 of the first heat-dissipation film 310 may be formed of or include a 2D material such as graphene and may electrically connect the device layer 120 and the first via layer V1. Likewise, the first portion 321 of the second heat-dissipation film 320 may electrically connect the device layer 120 and the second via layer V2. The heat-dissipation structure 300 may include a material having both high thermal conductivity and high electrical conductivity.

The first portion 311 of the first heat-dissipation film 310 may prevent diffusion of a metal material constituting the first-first via V11 and the first-second via V12. For example, the first portion 311 of the first heat-dissipation film 310 may prevent diffusion of copper ions constituting the first-first via V11 and the first-second via V12. The first portion 321 of the second heat-dissipation film 320 may prevent diffusion of a metal material constituting the second-first via V21, the second-second via V22, and the second-third via V23. For example, the first portion 321 of the second heat-dissipation film 320 may prevent diffusion of copper ions constituting the second-first via V21, the second-second via V22, and the second-third via V23.

Hereinafter, embodiments different from that of FIG. 2 are described. The same reference numerals denote the same elements, and a detailed description thereof is not repeated and only differences discussed.

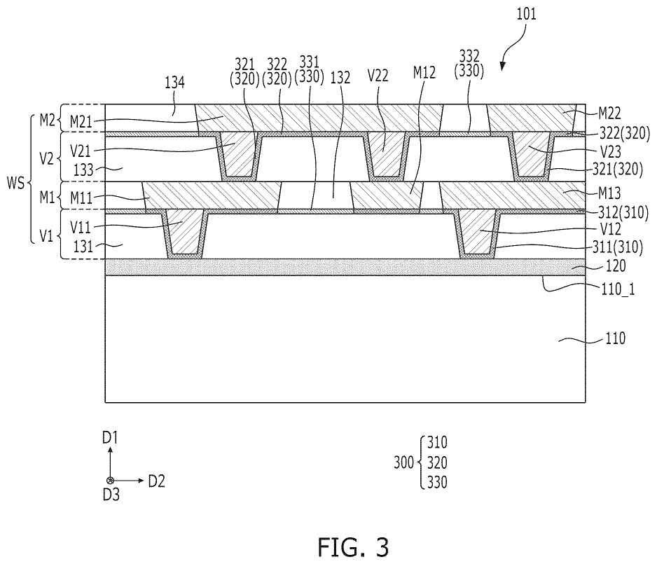

FIG. 3 is a cross-sectional view illustrating some components of a semiconductor chip according to some example embodiments of the present disclosure. In example embodiments, the semiconductor chip 101 of FIG. 3 may correspond to a portion of the semiconductor chip 100 of FIG. 1.

Referring to FIG. 3, in a semiconductor chip 101 according to some embodiments of the present disclosure, the first heat-dissipation film 310 may further include a second portion 312, and the second heat-dissipation film 320 may further include a second portion 322.

The second portion 312 of the first heat-dissipation film 310 may extend along a lower surface of the first metal layer M1. For example, the second portion 312 of the first heat-dissipation film 310 may extend along a lower surface of at least one of the first wirings M11, M12, and M13. For example, lower surfaces of at least one of the first wirings M11, M12, and M13 may contact an upper surface of the second portion 312 of the first heat-dissipation film 310. The second portion 312 of the first heat-dissipation film 310 may be disposed between the lower surface of at least one of the first wirings M11, M12, and M13 and the first interlayer insulating film 131. The second portion 322 of the second heat-dissipation film 320 may extend along a lower surface of the second metal layer M2. For example, the second portion 322 of the second heat-dissipation film 320 may extend along a lower surface of at least one of the second wirings M21 and M22. For example, lower surfaces of at least one of the second wirings M21 and M22 may contact an upper surface of the second portion 322 of the second heat-dissipation film 320. The second portion 322 of the second heat-dissipation film 320 may be formed between the lower surface of at least one of the second wirings M21 and M22 and the third interlayer insulating film 133. For convenience of description, the second portion 312 of the first heat-dissipation film 310 is described as extending along the lower surface of each of the first wirings M11, M12, and M13, and the second portion 322 of the second heat-dissipation film 320 is described as extending along the lower surface of each of the second wirings M21 and M22.

The second portion 312 of the first heat-dissipation film 310 may extend from the first portion 311 of the first heat-dissipation film 310. The second portion 312 of the first heat-dissipation film 310 may extend in the second direction D2 and/or the third direction D3, and may extend along the lower surface of the first metal layer M1. The second portion 312 of the first heat-dissipation film 310 may be bent from an upper end of the first portion 311 of the first heat-dissipation film 310. The second portion 312 of the first heat-dissipation film 310 and the first portion 311 of the first heat-dissipation film 310 may have a predetermined angle therebetween.

The second portion 312 of the first heat-dissipation film 310 may be part of a path for dissipating heat generated inside the semiconductor chip 101. For example, the second portion 312 of the first heat-dissipation film 310 may be part of a path for dissipating heat generated in the first vias V11 and V12 and the first wirings M11, M12, and M13. For example, the second portion 312 of the first heat-dissipation film 310 may provide a path for the first heat-dissipation film 310 to dissipate heat.

The second portion 312 of the first heat-dissipation film 310 may prevent diffusion of a metal material constituting the first-first wiring M11, the first-second wiring M12, and the first-third wiring M13. For example, the second portion 312 of the first heat-dissipation film 310 may prevent diffusion of copper ions constituting the first-first wiring M11, the first-second wiring M12, and the first-third wiring M13.

The second portion 322 of the second heat-dissipation film 320 may extend from the first portion 321 of the second heat-dissipation film 320. The second portion 322 of the second heat-dissipation film 320 may extend in the second direction D2 and/or the third direction D3, and may extend along the lower surface of the second metal layer M2. The second portion 322 of the second heat-dissipation film 320 may be bent from an upper end of the first portion 321 of the second heat-dissipation film 320, and the second portion 322 of the second heat-dissipation film 320 and the first portion 321 of the second heat-dissipation film 320 may have a predetermined angle therebetween.

The second portion 322 of the second heat-dissipation film 320 may be part of a path for dissipating heat generated inside the semiconductor chip 101. For example, the second portion 322 of the second heat-dissipation film 320 may be part of a path for dissipating heat generated in the second vias V21, V22, and V23 and the second wirings M21 and M22, thereby providing a path for the second heat-dissipation film 320 to dissipate heat.

The second portion 322 of the second heat-dissipation film 320 may prevent diffusion of a metal material constituting the second-first wiring M21 and the second-second wiring M22. For example, the second portion 322 of the second heat-dissipation film 320 may prevent diffusion of copper ions constituting the second-first wiring M21 and the second-second wiring M22.

In some embodiments, the first portions 311 and 321 and the second portions 312 and 322 may be formed of different materials. Both the first portions 311 and 321 and the second portions 312 and 322 may include materials having high thermal conductivity. For example, the first portions 311 and 321 may be formed of an insulating material, and the second portions 312 and 322 may be formed of a conductive material. Specifically, the first portions 311 and 321 may be formed of hBN, and the second portions 312 and 322 may be formed of graphene.

The heat-dissipation structure 300 may further include a heat-dissipation insulation structure 330. The heat-dissipation insulation structure 330 may include a first heat-dissipation insulation film 331 and a second heat-dissipation insulation film 332.

The first heat-dissipation insulation film 331 may be disposed between the second portions 312 of the first heat-dissipation film 310. The first heat-dissipation insulation film 331 may overlap the second portions 312 of the first heat-dissipation film 310 in the second direction D2. The first heat-dissipation insulation film 331 may have the same thickness in the first direction D1 as the second portions 312 of the first heat-dissipation film 310. For example, upper surfaces of the first heat-dissipation insulation film 331 and the second portions 312 of the first heat-dissipation film 310 may be coplanar with each other, and lower surfaces of the first heat-dissipation insulation film 331 and the second portions 312 of the first heat-dissipation film 310 may be coplanar with each other. The first heat-dissipation insulation film 331 may be formed by oxidizing a part of the first heat-dissipation film 310. The first heat-dissipation insulation film 331 may be disposed between the first wirings M11, M12, and M13. The first heat-dissipation insulation film 331 may be disposed on a lower surface of the second interlayer insulating film 132. The first heat-dissipation insulation film 331 may extend along the lower surface of the second interlayer insulating film 132. The first heat-dissipation insulation film 331 may contact the lower surface of the second interlayer insulating film 132 and an upper surface of the first interlayer insulating film 131.

The second heat-dissipation insulation film 332 may be disposed between the second portions 322 of the second heat-dissipation film 320. The second heat-dissipation insulation film 332 may overlap the second portions 322 in the second direction D2. The second heat-dissipation insulation film 332 may have the same thickness in the first direction D1 as the second portions 322 of the second heat-dissipation film 320. For example, upper surfaces of the second heat-dissipation insulation film 332 and the second portions 322 of the second heat-dissipation film 320 may be coplanar with each other, and lower surfaces of the second heat-dissipation insulation film 332 and the second portions 322 of the second heat-dissipation film 320 may be coplanar with each other. The second heat-dissipation insulation film 332 may be formed by oxidizing a part of the second heat-dissipation film 320. The second heat-dissipation insulation film 332 may be disposed between the second wirings M21 and M22. The second heat-dissipation insulation film 332 may be disposed on a lower surface of the fourth interlayer insulating film 134. The second heat-dissipation insulation film 332 may extend along the lower surface of the fourth interlayer insulating film 134. The second heat-dissipation insulation film 332 may contact the lower surface of the fourth interlayer insulating film 134 and an upper surface of the third interlayer insulating film 133.

The heat-dissipation insulation structure 330 may include an insulating material. The heat-dissipation insulation structure 330 may include an oxide obtained by oxidizing a conductive material. For example, the heat-dissipation insulation structure 330 may be formed of or include graphene oxide. In some embodiments, the heat-dissipation insulation structure 330 may be formed of or include silicon oxide, silicon nitride, or silicon oxynitride.

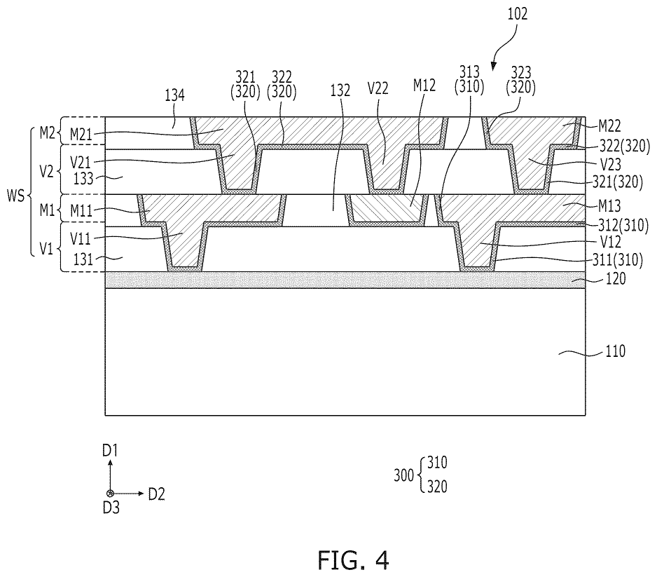

FIG. 4 is a cross-sectional view illustrating some components of a semiconductor chip according to some example embodiments of the present disclosure. In example embodiments, the semiconductor chip 102 of FIG. 4 corresponds to a portion of the semiconductor chip 100 of FIG. 1.

Referring to FIG. 4, in a semiconductor chip 102 according to some embodiments of the present disclosure, the first vias V11 and V12 of the first via layer V1 and the first wirings M11 and M13 of the first metal layer M1 may have an integrated structure, for example, and may be formed by a dual-damascene process. For example, each of the first vias V11 and V12 of the first via layer V1 may be a single structure, and each of the first wirings M11 and M13 of the first metal layer M1 may be a single structure.

The first heat-dissipation film 310 may further include a third portion 313, and the second heat-dissipation film 320 may further include a third portion 323.

The third portion 313 of the first heat-dissipation film 310 may extend along a side surface of the first metal layer M1. For example, the third portion 313 of the first heat-dissipation film 310 may extend along a side surface of at least one of the first wirings M11, M12, and M13. The third portion 313 of the first heat-dissipation film 310 may contact a side surface of at least one of the first wirings M11, M12, and M13. Upper surfaces of the third portion 313 of the first heat-dissipation film 310 may be coplanar with upper surfaces of the first wirings M11, M12, and M13. The third portion 323 of the second heat-dissipation film 320 may extend along a side surface of the second metal layer M2. For example, the third portion 323 of the second heat-dissipation film 320 may extend along a side surface of at least one of the second wirings M21 and M22. The third portion 323 of the second heat-dissipation film 320 may contact a side surface of at least one of the second wirings M21 and M22. Upper surfaces of the third portion 323 of the second heat-dissipation film 320 may be coplanar with upper surfaces of the second wirings M21 and M22. For convenience of description, the third portion 313 of the first heat-dissipation film 310 is described as extending along the side surfaces of each of the first wirings M11, M12, and M13, and the third portion 323 of the second heat-dissipation film 320 is described as extending along the side surfaces of each of the second wirings M21 and M22. For example, in these example embodiments, the third portion 313 of the first heat-dissipation film 310 contacts the side surfaces of each of the first wirings M11, M12, and M13, and the third portion 323 of the second heat-dissipation film 320 contacts the side surfaces of each of the second wirings M21 and M22.

The third portion 313 of the first heat-dissipation film 310 may extend from the second portion 312 of the first heat-dissipation film 310. The third portion 313 of the first heat-dissipation film 310 may be bent from an end of the second portion 312 of the first heat-dissipation film 310, and the third portion 313 of the first heat-dissipation film 310 and the second portion 312 of the first heat-dissipation film 310 may have a predetermined angle therebetween. Likewise, the third portion 323 of the second heat-dissipation film 320 may extend from the second portion 322 of the second heat-dissipation film 320 and may be bent from an end of the second portion 322 of the second heat-dissipation film 320, and the third portion 323 of the second heat-dissipation film 320 and the second portion 322 of the second heat-dissipation film 320 may have a predetermined angle therebetween.

The third portion 313 of the first heat-dissipation film 310 may be part of a path for dissipating heat generated inside the semiconductor chip 102. For example, the third portion 313 of the first heat-dissipation film 310 may be part of a path for dissipating heat generated in the first wirings M11, M12, and M13, thereby providing a path for the first heat-dissipation film 310 to dissipate heat.

The third portion 323 of the second heat-dissipation film 320 may be part of a path for dissipating heat generated inside the semiconductor chip 102. For example, the third portion 323 of the second heat-dissipation film 320 may be part of a path for dissipating heat generated in the second wirings M21 and M22, thereby providing a path for the second heat-dissipation film 320 to dissipate heat.

The third portion 313 of the first heat-dissipation film 310 may prevent diffusion of a metal material constituting the first-first wiring M11, the first-second wiring M12, and the first-third wiring M13. For example, the third portion 313 of the first heat-dissipation film 310 may prevent diffusion of copper ions constituting the first-first wiring M11, the first-second wiring M12, and the first-third wiring M13. The third portion 323 of the second heat-dissipation film 320 may prevent diffusion of a metal material constituting the second-first wiring M21 and the second-second wiring M22. For example, the third portion 323 of the second heat-dissipation film 320 may prevent diffusion of copper ions constituting the second-first wiring M21 and the second-second wiring M22.

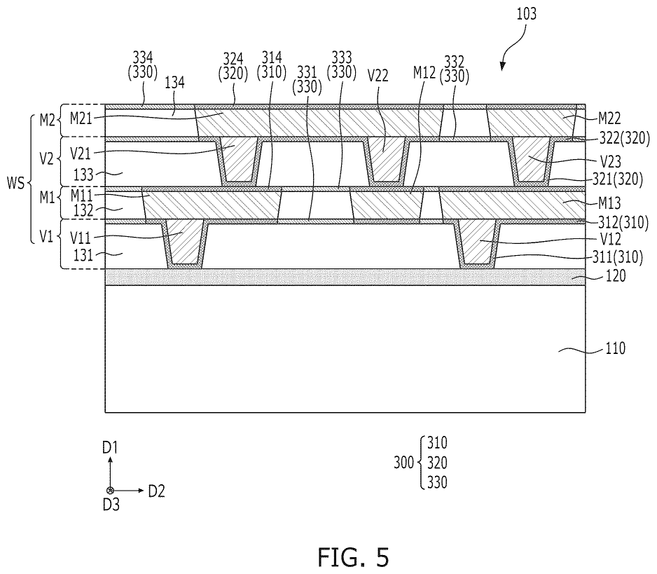

FIG. 5 is a cross-sectional view illustrating some components of a semiconductor chip according to some example embodiments of the present disclosure. In example embodiments, the semiconductor chip 103 of FIG. 5 may correspond to a portion of the semiconductor chip 100 of FIG. 1.

Referring to FIG. 5, in a semiconductor chip 103 according to some embodiments of the present disclosure, compared to the embodiments of FIG. 3, the first heat-dissipation film 310 may further include a fourth portion 314, and the second heat-dissipation film 320 may further include a fourth portion 324.

The fourth portions 314 of the first heat-dissipation film 310 may extend along upper surfaces of the first wirings M11, M12, and M13. The fourth portion 314 of the first heat-dissipation film 310 may be disposed on the upper surfaces of the first wirings M11, M12, and M13. The fourth portions 314 of the first heat-dissipation film 310 may be interposed between the first wirings M11, M12, and M13 and the first portions 321 of the second heat-dissipation film 320. The fourth portions 314 of the first heat-dissipation film 310 may contact the upper surfaces of the first wirings M11, M12, and M13 and the lower surfaces of the first portions 321 of the second heat-dissipation film 320.

The fourth portions 314 of the first heat-dissipation film 310 may be part of a path for dissipating heat generated inside the semiconductor chip 103. For example, the fourth portions 314 of the first heat-dissipation film 310 may be part of a path for dissipating heat generated in the first wirings M11, M12, and M13, thereby providing a path for the first heat-dissipation film 310 to dissipate heat.

The fourth portions 324 of the second heat-dissipation film 320 may extend along an upper surface of the second wirings M21 and M22. The fourth portions 324 of the second heat-dissipation film 320 may be disposed on the upper surfaces of the second wirings M21 and M22. The fourth portions 324 of the second heat-dissipation film 320 may contact the upper surfaces of the second wirings M21 and M22.

The fourth portions 324 of the second heat-dissipation film 320 may be part of a path for dissipating heat generated inside the semiconductor chip 103. For example, the fourth portions 324 of the second heat-dissipation film 320 may be part of a path for dissipating heat generated in the second wirings M21 and M22, thereby providing a path for the second heat-dissipation film 320 to dissipate heat.

The heat-dissipation insulation structure 330 may further include a third heat-dissipation insulation film 333 and a fourth heat-dissipation insulation film 334. The third heat-dissipation insulation film 333 may be provided between the second via layer V2 and the first metal layer M1. The fourth heat-dissipation insulation film 334 may be provided on the second metal layer M2.

The third heat-dissipation insulation film 333 may be disposed between the fourth portions 314 of the first heat-dissipation film 310. The third heat-dissipation insulation film 333 may overlap the fourth portions 314 of the first heat-dissipation film 310 in the second direction D2. For example, upper surfaces of the third heat-dissipation insulation film 333 may be coplanar with upper surfaces of the fourth portions 314 of the first heat-dissipation film 310, and lower surfaces of the third heat-dissipation insulation film 333 may be coplanar with lower surfaces of the fourth portions 314 of the first heat-dissipation film 310. The third heat-dissipation insulation film 333 may be disposed on an upper surface of the second interlayer insulating film 132. The third heat-dissipation insulation film 333 may extend along the upper surface of the second interlayer insulating film 132. For example, the third heat-dissipation insulation film 333 may contact an upper surface of the second interlayer insulating film 132 and a lower surface of the third interlayer insulating film 133.

The fourth heat-dissipation insulation film 334 may be disposed between the fourth portions 324 of the second heat-dissipation film 320. The fourth heat-dissipation insulation film 334 may overlap the fourth portions 324 of the second heat-dissipation film 320 in the second direction D2. For example, upper surfaces of the fourth heat-dissipation insulation film 334 may be coplanar with upper surfaces of the fourth portions 324 of the second heat-dissipation film 320, and lower surfaces of the fourth heat-dissipation insulation film 334 may be coplanar with lower surfaces of the fourth portions 324 of the second heat-dissipation film 320. The fourth heat-dissipation insulation film 334 may be disposed on an upper surface of the fourth interlayer insulating film 134. The fourth heat-dissipation insulation film 334 may extend along the upper surface of the fourth interlayer insulating film 134. For example, the fourth heat-dissipation insulation film 334 may contact an upper surface of the fourth interlayer insulating film 134.

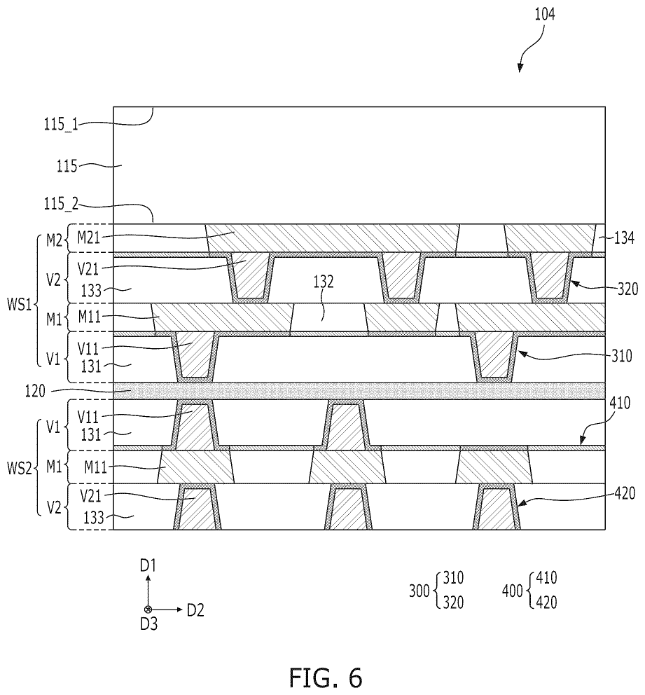

FIG. 6 is a cross-sectional view illustrating some components of a semiconductor chip according to some example embodiments of the present disclosure. In example embodiments, the semiconductor chip 104 of FIG. 6 may correspond to a portion of the semiconductor chip 100 of FIG. 1.

Referring to FIG. 6, a semiconductor chip 104 according to some embodiments of the present disclosure may include a first wiring structure WS1, a second wiring structure WS2, and a support substrate 115. The first wiring structure WS1 may be disposed on one surface of the device layer 120, and the second wiring structure WS2 may be disposed on another surface of the device layer 120. For example, the first wiring structure WS1 may be disposed on a front surface of the device layer 120, and the second wiring structure WS2 may be disposed on a back surface of the device layer 120. Hereinafter, the first wiring structure WS1 may be referred to as a front side wiring structure and the second wiring structure WS2 may be referred to as a back side wiring structure. Numbers of layers, numbers of vias and wirings, and their arrangement in the via layers and metal layers of the first wiring structure WS1 and the second wiring structure WS2 are merely illustrative and are not limited to those shown.

The first wiring structure WS1 may include a first via layer V1, a first metal layer M1, a second via layer V2, a second metal layer M2, and a first heat-dissipation structure 300. In example embodiments, in the first wiring structure WS1, the first via layer V1 may also be referred to as a front side via layer V1, the first metal layer M1 may also be referred to as a front side first metal layer M1, the second via layer V2 may also be referred to as a front side second via layer V2, and the second metal layer M2 may also be referred to as a front side second metal layer M2. The second wiring structure WS2 may include a first via layer V1, a first metal layer M1, a second via layer V2, and a second heat-dissipation structure 400. In example embodiments, in the second wiring structure WS2, the first via layer V1 may also be referred to as a back side first via layer V1, the first metal layer M1 may also be referred to as a back side first metal layer M1, and the second via layer V2 may also be referred to as a back side second via layer V2. Descriptions of the respective components of the first wiring structure WS1 and the second wiring structure WS2 are substantially identical to those described with reference to FIG. 3 above.

The first heat-dissipation structure 300 may include the first heat-dissipation film 310 and the second heat-dissipation film 320. The first heat-dissipation film 310 of the first heat-dissipation structure 300 may be provided in the first via layer V1 and the first metal layer M1 of the first wiring structure WS1, and the second heat-dissipation film 320 of the first heat-dissipation structure 300 may be provided in the second via layer V2 and the second metal layer M2 of the first wiring structure WS1.

The second heat-dissipation structure 400 may include a first heat-dissipation film 410 and a second heat-dissipation film 420. The first heat-dissipation film 410 of the second heat-dissipation structure 400 may be provided in the first via layer V1 and the first metal layer M1 of the second wiring structure WS2. The second heat-dissipation film 420 of the second heat-dissipation structure 400 may be provided in the second via layer V2 of the second wiring structure WS2. The first heat-dissipation film 410 of the second heat-dissipation structure 400 may be substantially the same as the first heat-dissipation film 310 of the second heat-dissipation structure 300 of FIG. 3, and the second heat-dissipation film 420 of the second heat-dissipation structure 400 may be substantially the same as the second heat-dissipation film 320 of the second heat-dissipation structure 300 of FIG. 3.

The first wiring structure WS1 may be electrically connected to the device layer 120. The first wiring structure WS1 may provide at least one of a signal line or a power line for various devices of the device layer 120. The second wiring structure WS2 may be electrically connected to the device layer 120. The second wiring structure WS2 may provide at least one of a power line or a signal line for various devices of the device layer 120. For example, the semiconductor chip according to the present disclosure may adopt a back side power-delivery-network (BSPDN) scheme in which power-supply wiring is disposed on a back surface of the semiconductor chip.

A support substrate 115 may be disposed on the first wiring structure WS1. A second surface 115_2 of the support substrate 115 may be disposed in contact with the first wiring structure WS1. A first surface 115_1 of the support substrate 115 may be referred to as an upper surface of the semiconductor chip 104. The support substrate 115 may be located on a side of the device layer 120 opposite to the second wiring structure WS2. The support substrate 115 may be bulk silicon or silicon-on-insulator SOI. Alternatively, the support substrate 115 may be formed of or include SiGe, SGOI, indium antimonide, lead telluride compounds, indium arsenide, indium phosphide, gallium arsenide, or gallium antimonide, but is not limited thereto.

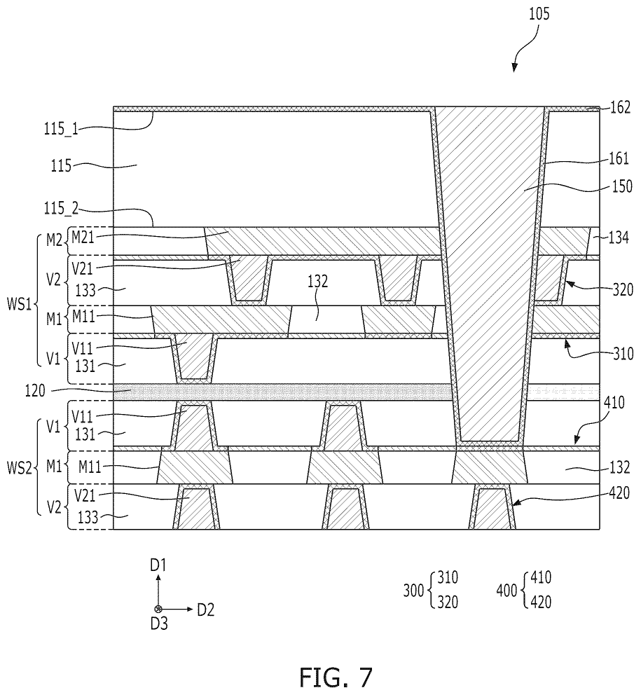

FIG. 7 is a cross-sectional view illustrating some components of a semiconductor chip according to some example embodiments of the present disclosure. In example embodiments, the semiconductor chip 105 of FIG. 7 may correspond to a portion of the semiconductor chip 100 of FIG. 1. In example embodiments, the through electrode 150 of FIG. 7 may be provided in place of or in addition to one or more of the through electrodes 155 of FIG. 1.

Referring to FIG. 7, a semiconductor chip 105 according to some embodiments of the present disclosure may further include a through electrode 150.

The through electrode 150 may penetrate at least a portion of the semiconductor chip 105. The through electrode 150 may penetrate the semiconductor chip 105 in the first direction D1. For example, the through electrode 150 may penetrate the support substrate 115 in the first direction D1. The through electrode 150 may penetrate the first surface 115_1 of the support substrate 115 in the first direction D1. The through electrode 150 may penetrate the first wiring structure WS1 and the device layer 120 in the first direction D1 and may overlap the first wiring structure WS1 and the device layer 120 in the second direction D2. For example, a portion of the device layer 120 may include a penetration region in which the through electrode 150 is formed. In some embodiments, the through electrode 150 may further penetrate a portion of the second wiring structure WS2 and may be connected to the second wiring structure WS2. For example, the through electrode 150 may contact at least one of a via layer and a metal layer constituting the second wiring structure WS2.

A through heat-dissipation film 161 may be in contact with the through electrode 150. The through heat-dissipation film 161 may extend along a side surface and a bottom surface of the through electrode 150. The through heat-dissipation film 161 may contact side and bottom surfaces of the through electrode 150. For example, the through heat-dissipation film 161 may have a cup shape surrounding the through electrode 150. In some embodiments, the through heat-dissipation film 161 may not be disposed on the bottom surface of the through electrode 150. For example, the bottom surface of the through electrode 150 may contact the second wiring structure WS2.

The through heat-dissipation film 161 may be disposed between the through electrode 150 and the support substrate 115. The through heat-dissipation film 161 may penetrate the first surface 115_1 of the support substrate 115 in the first direction D1. The through heat-dissipation film 161 may overlap the device layer 120 in the second direction D2; for example, the through heat-dissipation film 161 may penetrate the penetration region of the device layer 120 in the first direction D1. A bottom surface of the through heat-dissipation film 161 may contact the second wiring structure WS2.

The through heat-dissipation film 161 may prevent diffusion of a metal material constituting the through electrode 150. For example, the through heat-dissipation film 161 may prevent diffusion of copper ions constituting the through electrode 150 into the support substrate 115.

A surface heat-dissipation film 162 may be disposed on the semiconductor chip 105. The surface heat-dissipation film 162 may be disposed on the first surface 115_1 of the support substrate 115. The surface heat-dissipation film 162 may contact the first surface 115_1 of the support substrate 115. For example, the surface heat-dissipation film 162 may be disposed on an upper surface of the semiconductor chip 105. The surface heat-dissipation film 162 may be connected to the through heat-dissipation film 161 and may extend in the second direction D2.

The surface heat-dissipation film 162 may overlap the through electrode 150 in the second direction D2. At least a portion of the through electrode 150 may be located at a vertical level higher than the first surface 115_1 of the support substrate 115. The through electrode 150 may overlap the surface heat-dissipation film 162 in the second direction D2. For example, an upper portion of the through electrode 150 may overlap the surface heat-dissipation film 162 in the second direction D2. In some embodiments, an upper surface of the surface heat-dissipation film 162 may be coplanar with an upper surface of the through electrode 150.

The through heat-dissipation film 161 and the surface heat-dissipation film 162 may provide a path for dissipating heat generated from the semiconductor chip 105. For example, heat generated in the semiconductor chip 105 may be dissipated along the through electrode 150, the through heat-dissipation film 161, and/or the surface heat-dissipation film 162.

The through heat-dissipation film 161 and the surface heat-dissipation film 162 may include a material having high electrical conductivity. The through heat-dissipation film 161 and the surface heat-dissipation film 162 may be electrically connected to the through electrode 150. The through heat-dissipation film 161 and the surface heat-dissipation film 162 may include a conductive material. The through heat-dissipation film 161 and the surface heat-dissipation film 162 may also include a material having high thermal conductivity. For example, the through heat-dissipation film 161 and the surface heat-dissipation film 162 may be formed of or include graphene. In some embodiments, the through heat-dissipation film 161 and the surface heat-dissipation film 162 may include a 2D material including at least one of diamond-like carbon DLC, hexagonal boron nitride hBN, and a transition-metal dichalcogenide TMD.

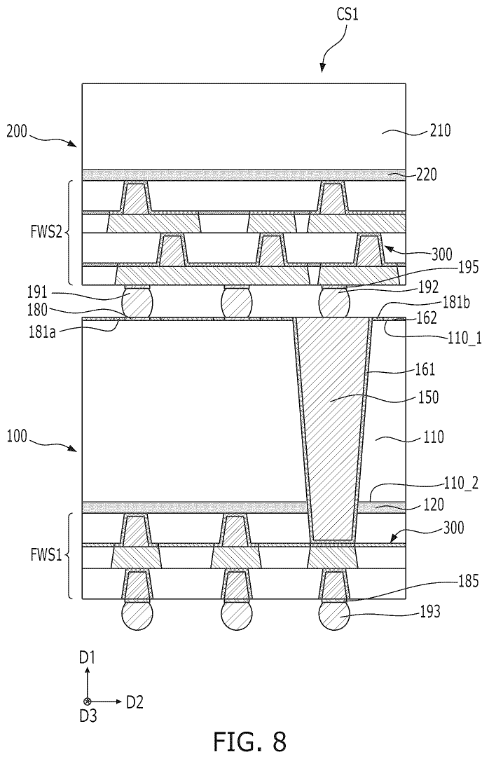

FIGS. 8-11 are cross-sectional views illustrating chip stacked structures according to some example embodiments of the present disclosure. In example embodiments, each the chip stack structures illustrated in FIGS. 8-11 may include one or more of the semiconductor chip 100 of FIG. 2, the semiconductor chip 101 of FIG. 3, the semiconductor chip 102 of FIG. 4, the semiconductor chip 103 of FIG. 5, the semiconductor chip 104 of FIG. 6, and the semiconductor chip 105 of FIG. 7.

Referring to FIG. 8, a chip stacked structure CS1 according to some embodiments of the present disclosure may include the first semiconductor chip 100, the second semiconductor chip 200, first connection terminals 191, second connection terminals 192, and lower terminals 193. The second semiconductor chip 200 may be stacked on the first semiconductor chip 100. The first connection terminals 191 and the second connection terminals 192 may be disposed between the first semiconductor chip 100 and the second semiconductor chip 200 and may connect the first semiconductor chip 100 and the second semiconductor chip 200. The lower terminals 193 may be disposed on a lower surface of the first semiconductor chip 100. Each of the lower terminals 193 may be disposed on a lower pad 185. The chip stacked structure CS1 may be mounted on a package substrate or a main board through the lower terminals 193.

The first semiconductor chip 100 may further include upper pads 180 and first and second surface insulation films 181a and 181b as compared with the semiconductor chip 105 of FIG. 7.

The first semiconductor chip 100 may include a first substrate 110, a first device layer 120, a first front side wiring structure FWS1, upper pads 180, a through electrode 150, a through heat-dissipation film 161, and a surface heat-dissipation film 162. Descriptions of the first substrate 110, the first device layer 120, and the first front side wiring structure FWS1 are substantially identical to those for the substrate 110, the device layer 120, and the wiring structure WS described with reference to FIGS. 2-4. For example, a heat-dissipation structure of the first front side wiring structure FWS1 may be referred to as a first front side heat-dissipation structure. In addition, a first via layer and a first metal layer of the first front side wiring structure FWS1 may be referred to as a first front side via layer and a first front side metal layer, respectively. That is, the first front side wiring structure FWS1 may include a first front side via layer including a first front side via disposed on the first device layer 120, a first front side metal layer including a first front side wiring disposed on the first front side via layer, and a first front side heat-dissipation structure including a first portion surrounding a bottom surface and a side surface of the first front side via.

The upper pads 180 may be provided on the first substrate 110. For example, the upper pads 180 may be disposed on a first surface 110_1 of the first substrate 110. The upper pads 180 may be disposed in the surface heat-dissipation film 162. The upper pads 180 may be surrounded by the surface heat-dissipation film 162. The upper pads 180 may be provided in plural numbers. The upper pads 180 may include at least one of Al, Cu, Ni, W, Pt, and Au, but materials constituting the upper pads 180 are not limited thereto.

The first connection terminals 191 may be disposed on the upper pads 180 of the first semiconductor chip 100. The second semiconductor chip 200 and the first semiconductor chip 100 may be electrically connected through the upper pads 180 and the first connection terminals 191.

The second connection terminals 192 may be disposed on the through electrodes 150 and may be electrically connected to the through electrodes 150. In some embodiments, a pad for attaching the second connection terminal 192 may be formed on the through electrode 150. In other embodiments, the second connection terminal 192 may be formed to directly contact the through electrode 150. The second connection terminals 192 may be connected to the first device layer 120 and the first front side wiring structure FSW1 of the first semiconductor chip 100 through the through electrodes 150.

The first connection terminals 191 and the second connection terminals 192 may be connected to the second device layer 220 and the second front side wiring structure FSW2 of the second semiconductor chip 200 through lower pads 195 disposed on a lower surface of the second semiconductor chip 200.

A first surface insulation film 181a and a second surface insulation film 181b may be disposed on the first surface 110_1 of the first substrate 110. The first surface insulation film 181a and the second surface insulation film 181b may contact the first surface 110_1 of the first substrate 110.

The first surface insulation film 181a may be disposed around the upper pads 180. The first surface insulation film 181a may prevent electrical conduction between the upper pads 180 and the surface heat-dissipation film 162. The first surface insulation film 181a may be disposed such that the upper pads 180 and the surface heat-dissipation film 162 are spaced apart from each other in the second direction D2. The first surface insulation film 181a may surround the upper pads 180. For example, the first surface insulation film 181a may contact side surfaces of the upper pads 180. An upper surface of the first surface insulation film 181a, upper surfaces of the upper pads 180, and an upper surface of the surface heat-dissipation film 162 may be coplanar, and a lower surface of the first surface insulation film 181a, lower surfaces of the upper pads 180, and a lower surface of the surface heat-dissipation film 162 may be coplanar. For example, the first surface insulation film 181a may overlap the upper pads 180 and the surface heat-dissipation film 162 in the second direction D2.

The second surface insulation film 181b may be disposed around the through electrodes 150 and may be disposed between the through heat-dissipation film 161 and the surface heat-dissipation film 162. The second surface insulation film 181b may prevent electrical conduction between the through electrodes 150 and/or the through heat-dissipation film 161 and the surface heat-dissipation film 162. For example, the second surface insulation film 181b may be disposed such that the through heat-dissipation film 161 and the surface heat-dissipation film 162 are spaced apart from each other in the second direction D2. The second surface insulation film 181b may surround the through heat-dissipation film 161. The second surface insulation film 181b may contact a portion of the side surface of the through heat-dissipation film 161. An upper surface of the second surface insulation film 181b may be coplanar with upper surfaces of the surface heat-dissipation film 162, the through heat-dissipation film 161, and the through electrode 150. For example, the second surface insulation film 181b may overlap the through electrode 150 and the surface heat-dissipation film 162 in the second direction D2.

The first surface insulation film 181a and the second surface insulation film 181b may include an insulating material. The first surface insulation film 181a and the second surface insulation film 181b may include an oxide obtained by oxidizing a conductive material. For example, the first surface insulation film 181a and the second surface insulation film 181b may be formed of or include graphene oxide. In some embodiments, the first surface insulation film 181a and the second surface insulation film 181b may be formed of or include silicon oxide, silicon nitride, or silicon oxynitride.

The second semiconductor chip 200 may include a second substrate 210, a second device layer 220, and a second front side wiring structure FSW2. Descriptions of the second front side wiring structure FSW2 are substantially identical to those for the wiring structure WS described with reference to FIGS. 2-4. For example, a heat-dissipation structure of the second front side wiring structure FSW2 may be referred to as a second front side heat-dissipation structure. Further, a first via layer and a first metal layer of the second front side wiring structure FSW2 may be referred to as a second front side via layer and a second front side metal layer, respectively. For example, the second front side wiring structure FSW2 may include a second front side via layer including a second front side via disposed on the second device layer 220, a second front side metal layer including a second front side wiring disposed on the second front side via layer, and a second front side heat-dissipation structure including a first portion surrounding a bottom surface and a side surface of the second front side via.

As described above, in the chip stacked structure CS1 according to some embodiments of the present disclosure, the first front side wiring structure FWS1 and the second front side wiring structure FSW2 of the respective first semiconductor chip 100 and second semiconductor chip 200 may perform signal transmission and/or power supply.

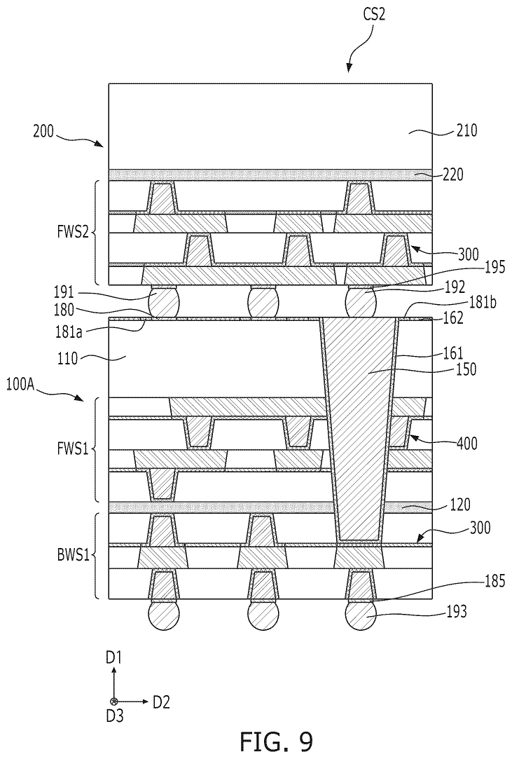

Referring to FIG. 9, a chip stacked structure CS2 according to the embodiment of FIG. 9 may differ from the embodiment of FIG. 8 in that a structure of the first semiconductor chip 100A is different from that of the first semiconductor chip 100 of FIG. 8.

The first semiconductor chip 100A may include a first substrate 110, a first front side wiring structure FWS1, and a first back side wiring structure BWS1. A heat-dissipation structure of the first front side wiring structure FWS1 may be referred to as a first front side heat-dissipation structure, and a heat-dissipation structure of the first back side wiring structure BWS1 may be referred to as a first back side heat-dissipation structure.

The first substrate 110 may be a support substrate for forming the first back side wiring structure BWS1 and may be disposed on the first front side wiring structure FWS1. The first substrate 110 may be disposed on an upper surface of the first front side wiring structure FWS1.

The first front side wiring structure FWS1 and the first back side wiring structure BWS1 may be located opposite to each other with respect to the first device layer 120. For example, the first front side wiring structure FWS1 may be disposed on a front surface of the first device layer 120, and the first back side wiring structure BWS1 may be disposed on a back surface of the first device layer 120.

The first front side wiring structure FWS1 may provide signal lines for various devices of the first device layer 120. The first back side wiring structure BWS1 may provide power lines for various devices of the first device layer 120. That is, the first semiconductor chip 100A may adopt a BSPDN scheme in which power-supply wiring is disposed on a back surface of the semiconductor chip.

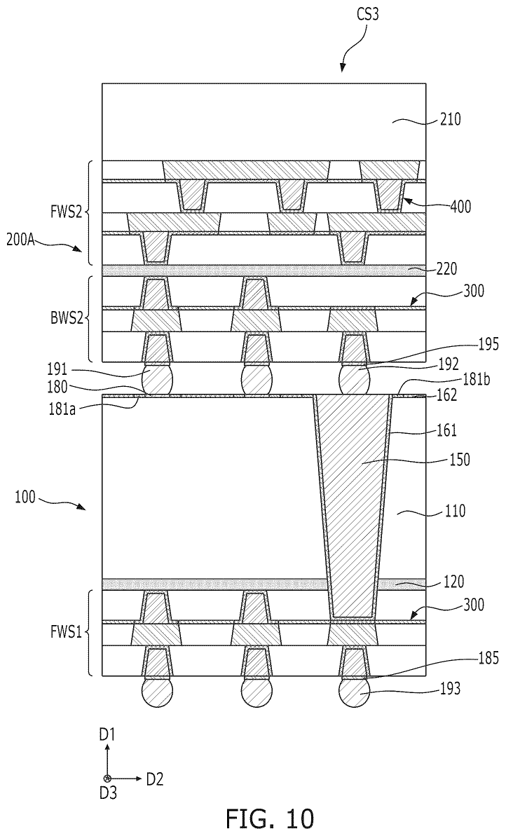

Referring to FIG. 10, a chip stacked structure CS3 according to the embodiment of FIG. 10 may differ from the embodiment of FIG. 8 in that a structure of the second semiconductor chip 200A is different.

The second semiconductor chip 200A may include a second substrate 210, a second front side wiring structure FSW2, and a second back side wiring structure BWS2. A heat-dissipation structure of the second front side wiring structure FSW2 may be referred to as a second front side heat-dissipation structure, and a heat-dissipation structure of the second back side wiring structure BWS2 may be referred to as a second back side heat-dissipation structure.

The second substrate 210 may be a support substrate for forming the second back side wiring structure BWS2 and may be disposed on the second front side wiring structure FSW2. The second substrate 210 may be disposed on an upper surface of the second front side wiring structure FSW2.

The second front side wiring structure FSW2 and the second back side wiring structure BWS2 may be located opposite to each other with respect to the second device layer 220. For example, the second front side wiring structure FSW2 may be disposed on a front surface of the second device layer 220, and the second back side wiring structure BWS2 may be disposed on a back surface of the second device layer 220.

The second front side wiring structure FSW2 may provide signal lines for various devices of the second device layer 220. The second back side wiring structure BWS2 may provide power lines for various devices of the second device layer 220. For example, the second semiconductor chip 200A may adopt a BSPDN scheme in which power-supply wiring is disposed on a back surface of the semiconductor chip.

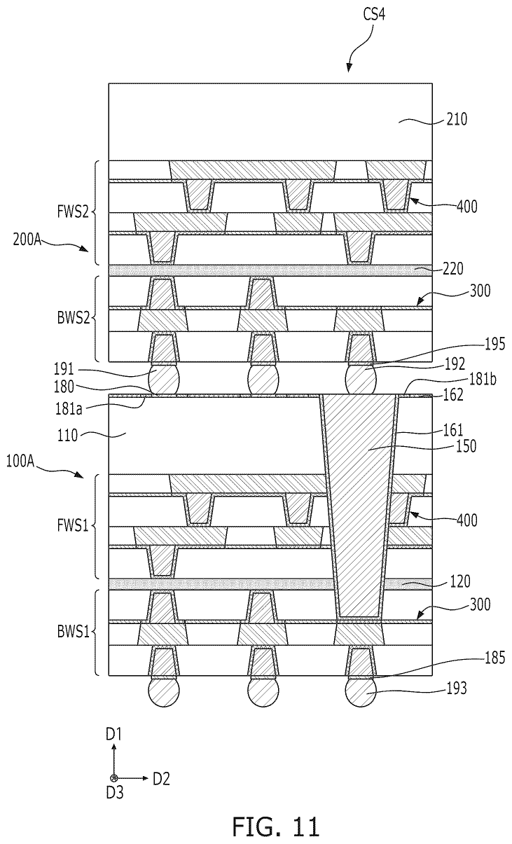

Referring to FIG. 11, a chip stacked structure CS4 according to the embodiment of FIG. 11 may differ from the embodiment of FIG. 8 in that structures of both the first semiconductor chip 100A and the second semiconductor chip 200A are different.

The first semiconductor chip 100A may include a first substrate 110, a first front side wiring structure FWS1, and a first back side wiring structure BWS1. A heat-dissipation structure of the first front side wiring structure FWS1 may be referred to as a first front side heat-dissipation structure, and a heat-dissipation structure of the first back side wiring structure BWS1 may be referred to as a first back side heat-dissipation structure.

The first substrate 110 may be a support substrate for forming the first back side wiring structure BWS1 and may be disposed on the first front side wiring structure FWS1. The first substrate 110 may be disposed on an upper surface of the first front side wiring structure FWS1.

The first front side wiring structure FWS1 and the first back side wiring structure BWS1 may be located opposite to each other with respect to the first device layer 120. For example, the first front side wiring structure FWS1 may be disposed on a front surface of the first device layer 120, and the first back side wiring structure BWS1 may be disposed on a back surface of the first device layer 120.

The first front side wiring structure FWS1 may provide signal lines for various devices of the first device layer 120. The first back side wiring structure BWS1 may provide power lines for various devices of the first device layer 120. That is, the first semiconductor chip 100A may adopt a BSPDN scheme in which power-supply wiring is disposed on a back surface of the semiconductor chip.

The second semiconductor chip 200A may include a second substrate 210, a second front side wiring structure FSW2, and a second back side wiring structure BWS2. A heat-dissipation structure of the second front side wiring structure FSW2 may be referred to as a second front side heat-dissipation structure, and a heat-dissipation structure of the second back side wiring structure BWS2 may be referred to as a second back side heat-dissipation structure.

The second substrate 210 may be a support substrate for forming the second back side wiring structure BWS2 and may be disposed on the second front side wiring structure FSW2. The second substrate 210 may be disposed on an upper surface of the second front side wiring structure FSW2.

The second front side wiring structure FSW2 and the second back side wiring structure BWS2 may be located opposite to each other with respect to the second device layer 220. For example, the second front side wiring structure FSW2 may be disposed on a front surface of the second device layer 220, and the second back side wiring structure BWS2 may be disposed on a back surface of the second device layer 220.

The second front side wiring structure FSW2 may provide signal lines for various devices of the second device layer 220. The second back side wiring structure BWS2 may provide power lines for various devices of the second device layer 220. That is, the second semiconductor chip 200A may adopt a BSPDN scheme in which power-supply wiring is disposed on a back surface of the semiconductor chip.

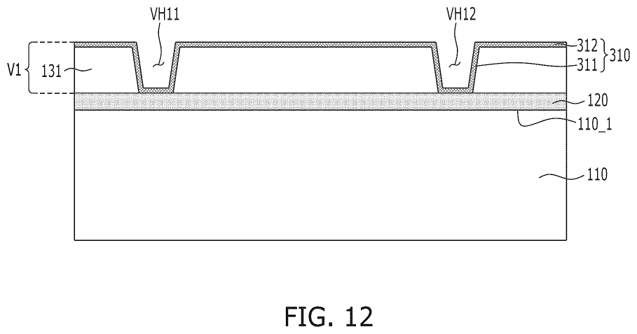

FIGS. 12-22 are cross-sectional views illustrating methods of manufacturing a semiconductor chip and a chip stacked structure according to some example embodiments of the present disclosure.

Referring to FIG. 12, the device layer 120 may be formed on the substrate 110. For example, the device layer 120 may be formed on a first surface 110_1 of the substrate 110. The device layer 120 may contact the first surface 110_1 of the substrate 110.

Next, the first via layer V1 may be formed on the device layer 120. For example, the first via layer V1 may be formed by a damascene process.

In some embodiments, a first interlayer insulating film 131 may be formed on the device layer 120. The first interlayer insulating film 131 may contact an upper surface of the device layer 120. Subsequently, a portion of the first interlayer insulating film 131 may be removed. For example, a mask pattern may be formed on an upper surface of the first interlayer insulating film 131, and a portion exposed by the mask pattern may be removed. Portions of the first interlayer insulating film 131 may thus be removed to form first via holes. For example, the first via holes may include first-first via hole VH11 and first-second via hole VH12. Numbers and positions of the first via holes are merely illustrative and may be provided in greater numbers.

The first heat-dissipation film 310 may be formed in the first via layer V1. The first heat-dissipation film 310 may be conformally formed by processes such as CVD or PVD. Specifically, the first heat-dissipation film 310 may be formed on side surfaces of the first-first via hole VH11 and the first-second via hole VH12 and on an upper surface of the first interlayer insulating film 131. The first heat-dissipation film 310 may contact the inner side surfaces of the first interlayer insulating film 131 and the upper surface of the first interlayer insulating film 131. Portions formed along the side surfaces of the first-first via hole VH11 and the first-second via hole VH12 become the first portion 311 of the first heat-dissipation film 310, and a portion formed along the upper surface of the first interlayer insulating film 131 becomes the second portion 312 of the first heat-dissipation film 310. In some embodiments, a portion of the first heat-dissipation film 310 on the first interlayer insulating film 131 may be removed. For example, a CMP process may remove a portion of the first heat-dissipation film 310 on the first interlayer insulating film 131, leaving only the first portion 311 of the first heat-dissipation film 310.

The first heat-dissipation film 310 may be formed of or include a 2D material. The first heat-dissipation film 310 may be formed of or include a conductive material. For example, the first heat-dissipation film 310 may be formed of graphene. In some embodiments, the first heat-dissipation film 310 may be formed of at least one of diamond-like carbon DLC, hBN, and a TMD.

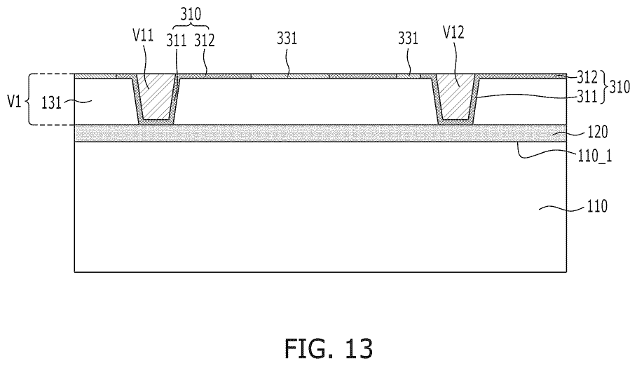

Referring to FIG. 13, the first vias V11 and V12 may be formed. Specifically, the first-first via V11 may be formed in the first-first via hole VH11, and the first-second via V12 may be formed in the first-second via hole VH12. A seed layer may be conformally disposed in the first-first via hole VH11 and the first-second via hole VH12, and a plating process using the seed layer as an electrode may form the first-first via V11 and the first-second via V12. For example, the first vias V11 and V12 may include Cu. In some embodiments, the first vias V11 and V12 may include W or Co and may be formed by CVD.

Next, a planarization process may be performed on an upper surface of the first via layer V1. For example, a CMP process may be performed on the upper surface of the first via layer V1. In example embodiments, upper surfaces of the first-first via V11, the first-second via V12, and the first heat-dissipation film 310 may be coplanar.

Next, a first heat-dissipation insulation film 331 may be formed on portions of the first heat-dissipation film 310 except portions where wirings are to be formed. The first heat-dissipation insulation film 331 may include an insulating material. For example, a mask pattern may be disposed on the first heat-dissipation film 310 at positions where wirings are to be formed, and an oxidation process may be performed on portions exposed by the mask pattern. For example, a chemical oxidation process supplying an oxidizer, irradiation of a laser or an electron beam onto the surface, plasma treatment, or application of a voltage to induce oxidation may be used, thereby forming an oxide obtained by oxidizing a conductive material constituting the first heat-dissipation film 310.

In some embodiments, a portion of the first heat-dissipation film 310 may be removed and an insulating material may be filled to form the first heat-dissipation insulation film 331. An upper surface of the first heat-dissipation insulation film 331 may be coplanar with an upper surface of the remaining portion of the first heat-dissipation film 310.

For example, the first heat-dissipation insulation film 331 may be formed of or include graphene oxide. In some embodiments, the first heat-dissipation insulation film 331 may include an insulating material having high thermal conductivity.

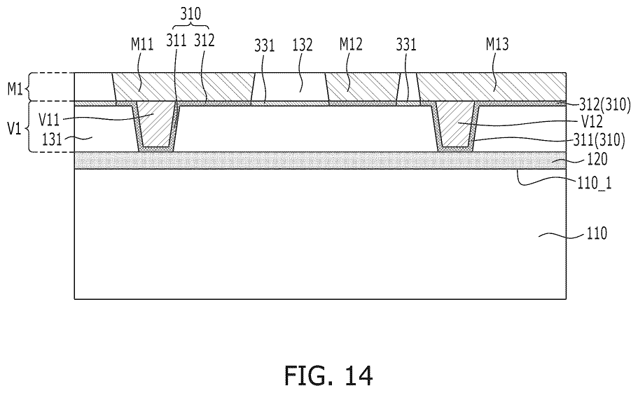

Referring to FIG. 14, the first metal layer M1 may be formed on the first via layer V1.

The second interlayer insulating film 132 may be formed on the first via layer V1. Then, portions of the second interlayer insulating film 132 may be removed to form wiring trenches. The wiring trenches may be formed on the first heat-dissipation film 310 and the first vias V11 and V12. The second interlayer insulating film 132 may remain on the first heat-dissipation insulation film 331. That is, portions of the second interlayer insulating film 132 on the first heat-dissipation insulation film 331 may not be removed, whereas portions on the first heat-dissipation film 310 and the first vias V11 and V12 may be removed. For example, the second interlayer insulating film 132 may contact an entire upper surface of the first heat-dissipation insulation film 331.

First wirings M11, M12, and M13 may be formed in the wiring trenches. The first-first wiring M11 and the first-third wiring M13 may contact the entire upper surfaces of the first-first via V11 and the first-second via V12. The first-first wiring M11, the first-second wiring M12, and the first-third wiring M13 may be formed by conformally disposing a seed layer and performing a plating process using the seed layer as an electrode. For example, the first-first wiring M11, first-second wiring M12 and first-third wiring M13 may include Cu. In some embodiments, the first wirings M11, M12, and M13 may include W or Co and may be formed by CVD.

Next, a planarization process may be performed on an upper surface of the first metal layer M1. For example, a CMP process may be performed on the upper surface of the first metal layer M1. Upper surfaces of the first-first wiring M11, the first-second wiring M12, and the first-third wiring M13 may be coplanar with the remaining portion of the second interlayer insulating film 132.

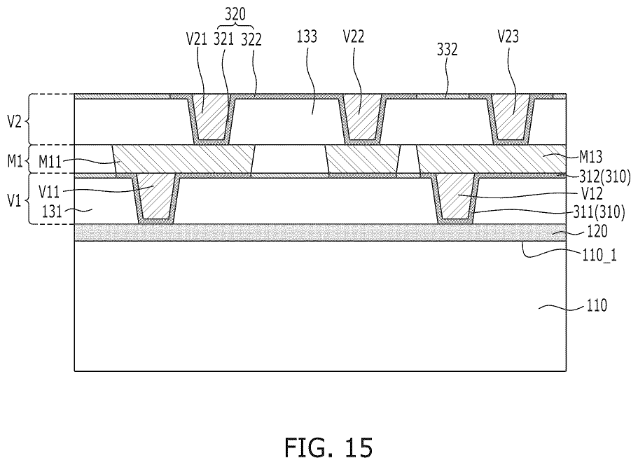

Referring to FIG. 15, the second vias V21, V22, and V23 may be formed. The methods of forming the second vias V21, V22, and V23 may be substantially identical to the methods of forming the first vias V11 and V12 described with reference to FIGS. 12 and 13. For example, a third interlayer insulating film 133 may be formed on the first metal layer M1. The third interlayer insulating film 133 may contact upper surfaces of the first metal layer M1 and the second interlayer insulating film 132.

A mask pattern may be formed on an upper surface of the third interlayer insulating film 133, and portions of the third interlayer insulating film 133 may thus be removed to form second via holes. A second heat-dissipation film 320 may be formed on side surfaces of the second via holes and on an upper surface of the third interlayer insulating film 133. The second heat-dissipation film 320 may contact inner side surfaces of the third interlayer insulating film 133 and the upper surface of the third interlayer insulating film 133.

In some embodiments, a portion of the second heat-dissipation film 320 on the third interlayer insulating film 133 may be removed. For example, a CMP process may remove a portion of the second heat-dissipation film 320 on the third interlayer insulating film 133, leaving only the first portion 321 of the second heat-dissipation film 320.

Next, the second vias V21, V22, and V23 may be formed. For example, a seed layer may be conformally disposed in the second via holes, and a plating process using the seed layer as an electrode may form the second vias V21, V22, and V23.

Next, a planarization process may be performed on an upper surface of the second via layer V2. For example, a CMP process may be performed on the upper surface of the second via layer V2. In example embodiments, upper surfaces of the second vias V21, V22, and V23 and the first heat-dissipation film 310 may be coplanar.

Next, a second heat-dissipation insulation film 332 may be formed on portions of the second heat-dissipation film 320 except portions where second wirings are to be formed. The methods of forming the second heat-dissipation insulation film 332 may be substantially identical to those of forming the first heat-dissipation insulation film 331 described with reference to FIG. 13. An upper surface of the second heat-dissipation insulation film 332 may be coplanar with an upper surface of the remaining portion of the second heat-dissipation film 320.

As described above, an oxide obtained by oxidizing a conductive material constituting the second heat-dissipation film 320 may be formed. For example, the second heat-dissipation insulation film 332 may be formed of or include graphene oxide. In some embodiments, the second heat-dissipation insulation film 332 may include an insulating material having high thermal conductivity.

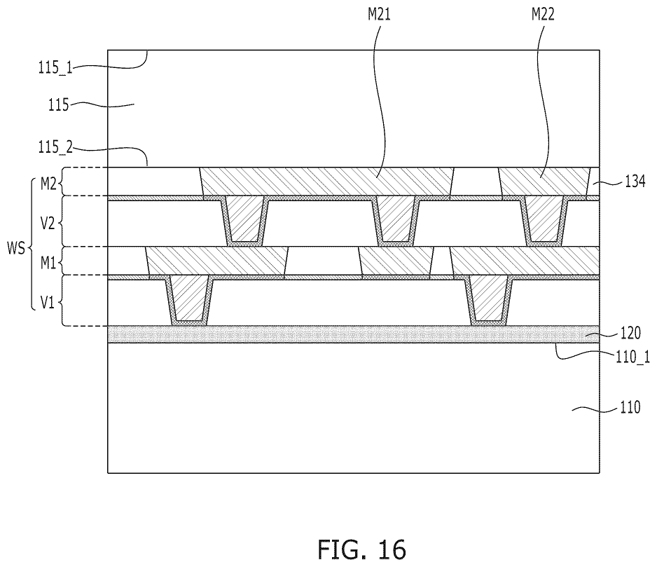

Referring to FIG. 16, the second metal layer M2 may be formed on the second via layer V2. The methods of forming the second metal layer M2 may be substantially identical to those of forming the first metal layer M1 described with reference to FIG. 14. Upper surfaces of the second wirings M21 and M22 may be coplanar with an upper surface of the fourth interlayer insulating film 134.

Next, the support substrate 115 may be formed on the wiring structure WS. The first surface 115_1 of the support substrate 115 may face the same direction as the first surface 110_1 of the substrate 110. The second surface 115_2 of the support substrate 115 may face the wiring structure WS. The second surface 115_2 of the support substrate 115 may contact upper surfaces of the second wirings M21 and M22 and an upper surface of the fourth interlayer insulating film 134. An oxide film for bonding may be formed between the support substrate 115 and the wiring structure WS. For example, a silicon oxide film may be interposed between the support substrate 115 and the wiring structure WS, thereby attaching the support substrate 115.

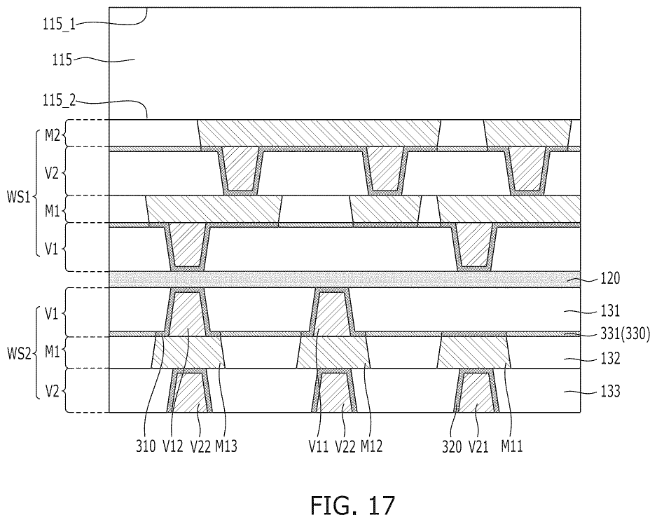

Referring to FIG. 17, the second wiring structure WS2 may be formed on a back surface of the device layer 120. Hereinafter, the wiring structure disposed on the front surface of the device layer 120 may be referred to as the first wiring structure WS1 or the front side wiring structure WS1.

The substrate 110 disposed on the back surface of the device layer 120 may be removed. For example, the substrate 110 may be removed by a CMP process. Subsequently, the first via layer V1, the first metal layer M1, and the second via layer V2 may be sequentially formed on the back surface of the device layer 120. The methods of forming the first via layer V1, the first metal layer M1, and the second via layer V2 of the second wiring structure WS2 may be substantially identical to those described with reference to FIGS. 12-14. In this manner, the second wiring structure WS2 may be formed.

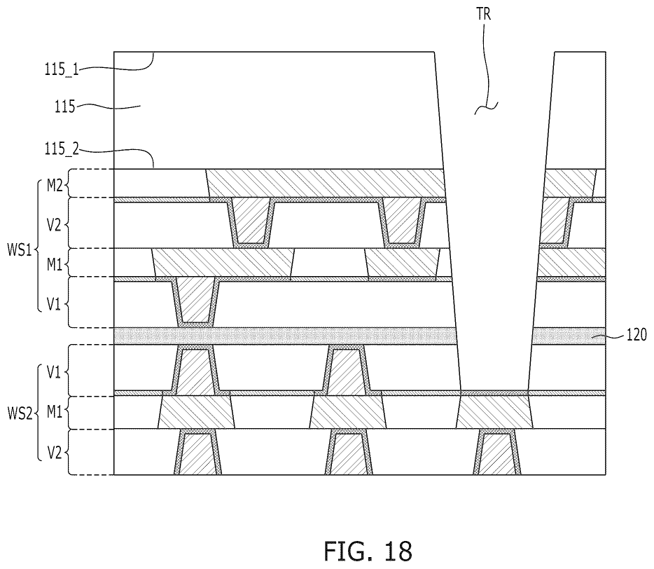

Referring to FIG. 18, a trench TR may be formed in the semiconductor chip. Such trench TR may be used to form a through electrode or a through heat-dissipation film. The trench TR may penetrate the support substrate 115 and may be formed by an etching process. For example, the trench TR may be formed by a wet etching or a dry etching process. By the etching process, a portion of the support substrate 115 may be removed.

The trench TR may be formed until the trench TR reaches an upper surface of the second wiring structure WS2 or penetrates a portion of the second wiring structure WS2. A portion of the second wiring structure WS2 may be exposed through the trench TR. In some embodiments, the trench TR may be formed such that the trench TR penetrates at least one of a plurality of wiring patterns constituting the second wiring structure WS2.

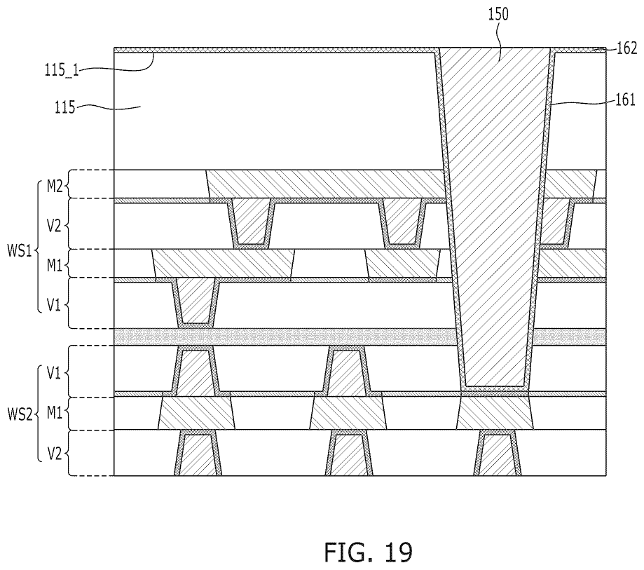

Referring to FIG. 19, the surface heat-dissipation film 162 may be formed on the first surface 115_1 of the support substrate 115, and the through heat-dissipation film 161 may be formed inside the trench TR. The through heat-dissipation film 161 may contact surfaces of the first via layer V1, the first metal layer M1, the second via layer V2, and the second metal layer M2 of the first wiring structure WS1, side surfaces of device layer 120 between the first wiring structures WS1 and the second wiring structure WS2, side surfaces of the first via layer V1 of second wiring structure WS2, and an upper surface of the second portion 312 of the first heat-dissipation film 310 of the first via layer V1 of the second wiring structure WS2.

For example, the through heat-dissipation film 161 may contact side surfaces of one or more of the first vias V11 and V12, the first interlayer insulating film 131, the first heat-dissipation film 310, and the first heat-dissipation insulation film 331 of the first wiring substrate WS1. In addition, the through heat-dissipation film 161 may contact side surfaces of one or more of the first wirings M11, M12, and M13, and the second interlayer insulating film 132 of the first wiring substrate WS1. Further, the through heat-dissipation film 161 may contact side surfaces of one or more of the second vias V21, V22, and V23, the third interlayer insulating film 133, the second heat-dissipation film 320, and the second heat-dissipation insulation film 333 of the first wiring substrate WS1. Additionally, the through heat-dissipation film 161 may contact side surfaces of one or more of the second wirings M21 and M22 and the fourth interlayer insulating film 134 of the first wiring substrate WS1. The through heat-dissipation film 161 may contact side surfaces of the support substrate 115, and the surface heat-dissipation film 162 may contact the first surface 115_1 of the support substrate 115.

The surface heat-dissipation film 162 and the through heat-dissipation film 161 may be integrally formed. The surface heat-dissipation film 162 and the through heat-dissipation film 161 may include a conductive material. For example, the surface heat-dissipation film 162 and the through heat-dissipation film 161 may be formed of graphene, in single-layer or multilayer form. The surface heat-dissipation film 162 and the through heat-dissipation film 161 may be formed by conformal CVD or by sputtering or PVD. In some embodiments, although formed of the same material, the surface heat-dissipation film 162 and the through heat-dissipation film 161 may be formed by different processes.

A conductive material may be filled inside the trench TR to form the through electrode 150. The conductive material may include Cu, W, polysilicon, or Al, etc. For example, a seed layer may be formed inside the trench TR and an electroplating process using the seed layer as an electrode may fill the conductive material. The conductive material may cover the seed layer inside the trench TR. In some embodiments, a planarization process may be performed on an upper surface of the conductive material.

In some embodiments, the surface heat-dissipation film 162 and the through heat-dissipation film 161 may be formed of different materials. The surface heat-dissipation film 162 and the through heat-dissipation film 161 may both include a material having high thermal conductivity. In some embodiments, the through heat-dissipation film 161 may be formed of an insulating material and the surface heat-dissipation film 162 may be formed of a conductive material. For example, the through heat-dissipation film 161 may be formed of hBN and the surface heat-dissipation film 162 may be formed of graphene.

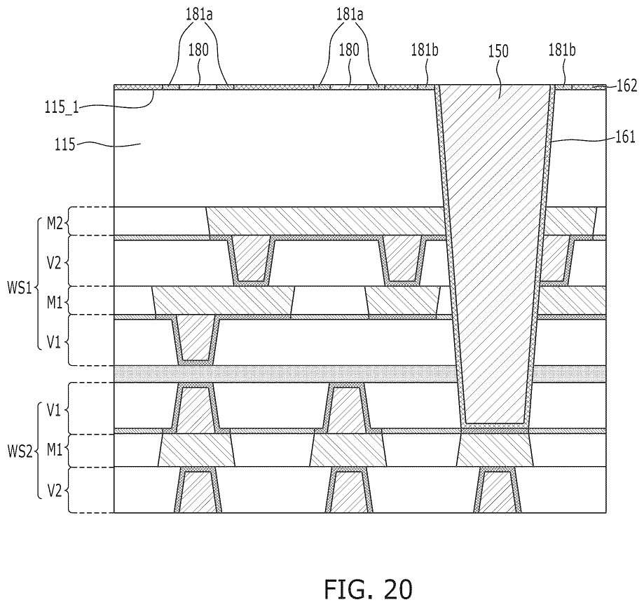

Referring to FIG. 20, the upper pads 180 and the first and second surface insulation films 181a and 181b may be formed on the surface heat-dissipation film 162.

A mask pattern may be disposed on the surface heat-dissipation film 162 and the through heat-dissipation film 161. For example, the mask pattern may cover a portion of the surface heat-dissipation film 162 while covering the entire through heat-dissipation film 161. The mask pattern may expose regions where the first surface insulation film 181a and the second surface insulation film 181b are to be formed.

An oxidation process may be performed on portions of the surface heat-dissipation film 162 exposed by the mask pattern. For example, a chemical oxidation process supplying an oxidizer, irradiation of a laser or an electron beam onto the surface, plasma treatment, or application of a voltage to the surface heat-dissipation film 162 may oxidize the exposed portions, thereby forming an oxide obtained by oxidizing a conductive material constituting the surface heat-dissipation film 162.

As described above, the first and second surface insulation films 181a and 181b may be formed by oxidizing portions of the surface heat-dissipation film 162. The first surface insulation film 181a and the second surface insulation film 181b may include an oxide obtained by oxidizing a conductive material. Therefore, the oxide constituting the first surface insulation film 181a and the second surface insulation film 181b may have insulating properties.

Alternatively, portions of the surface heat-dissipation film 162 may be removed and an insulating material may be filled to form the first and second surface insulation films 181a and 181b.

For example, the first surface insulation film 181a and the second surface insulation film 181b may be formed of or include graphene oxide obtained by oxidizing graphene.

The first and second surface insulation films 181a and 181b may be formed on the first surface 115_1 of the support substrate 115. For example, the first and second surface insulation films 181a and 181b may be formed in partial regions of the surface heat-dissipation film 162. Specifically, the first surface insulation film 181a may be formed at positions where the upper pads 180 are to be formed, and the second surface insulation film 181b may be formed around positions where the through electrode 150 is formed.

The upper pads 180 may be formed on the first surface insulation film 181a. The upper pads 180 may be formed by depositing a metal material of the first surface insulating film 181a. A lower surface of each upper pad 180 may contact an upper surface of the first surface insulation film 181a. In some embodiments, a pad for attaching the second connection terminal 192 may be formed on the through electrode 150.

In some embodiments, during deposition of the upper pads 180, a portion of the first surface insulation film 181a may melt and may be combined with the upper pads 180. While the first surface insulation film 181a melts, the upper pads 180 may become substantially coplanar with the first surface insulation film 181a. In some embodiments, a seed layer may be conformally disposed under the upper pads 180 and a plating process using the seed layer as an electrode may form the upper pads 180.

In this manner, the first semiconductor chip 100 may be manufactured. Hereinafter, a method of manufacturing the chip stacked structure CS by stacking the second semiconductor chip 200 on the first semiconductor chip 100 is described.

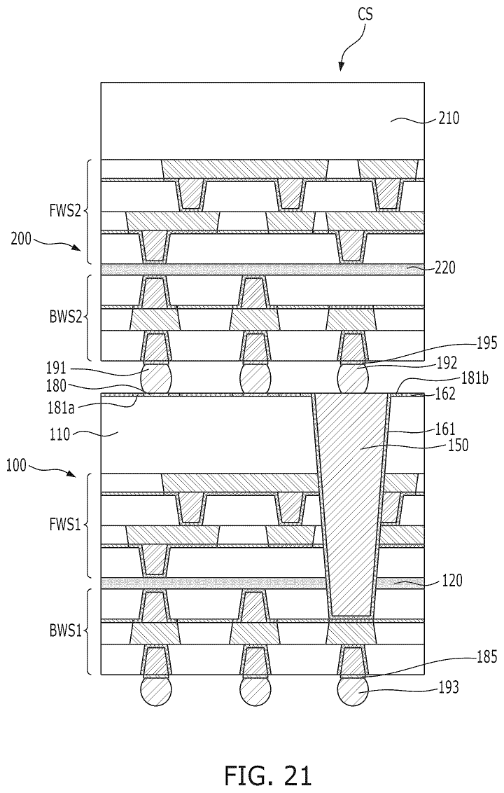

Referring to FIG. 21, the first semiconductor chip 100 may include the first front side wiring structure FWS1 and the first back side wiring structure BWS1, and the second semiconductor chip 200 may include the second front side wiring structure FSW2 and the second back side wiring structure BWS2.

The first connection terminals 191 may be attached on the upper pads 180 of the first semiconductor chip 100, and the second connection terminals 192 may be attached on the through electrode 150 of the first semiconductor chip 100. The second semiconductor chip 200 may be stacked on the first semiconductor chip 100. While the second semiconductor chip 200 is stacked on the first semiconductor chip 100, a reflow process may fuse the first connection terminals 191 and the second connection terminals 192 with connection terminals (for example, solder balls) attached to the second semiconductor chip 200.

In the manufacturing method for a semiconductor chip and a chip stacked structure according to the present disclosure, although the first semiconductor chip 100 and the second semiconductor chip 200 are illustrated as adopting a BSPDN scheme in which power-supply wiring is disposed on a back surface of the semiconductor chip, the present disclosure is not limited thereto.

Although the present disclosure has been described above with reference to limited embodiments and drawings, the present disclosure is not limited thereto, and various modifications and alterations can be made by those skilled in the art within the scope of the technical idea of the present disclosure and the equivalents defined by the claims to be described below.

What is claimed is:

1. A semiconductor chip, comprising:
a device layer having a first surface and a second surface opposite to the first surface; and
a first wiring structure on the first surface of the device layer,
wherein the first wiring structure comprises:
a first via layer comprising a first via;
a first metal layer comprising a first wiring, the first metal layer being stacked on the first via layer in a first direction perpendicular to the first surface of the device layer; and
a first heat-dissipation structure comprising a first heat-dissipation film including a first portion surrounding a bottom surface and a side surface of the first via, the first heat-dissipation structure comprising a 2D material, and
wherein an upper surface of the first portion of the first heat-dissipation film contacts a lower surface of the first wiring.

2. The semiconductor chip as claimed in claim 1, wherein the first heat-dissipation film further comprises a second portion extending along the lower surface of the first wiring of the first metal layer.

3. The semiconductor chip as claimed in claim 2,
wherein the first heat-dissipation film further comprises a third portion extending from the second portion along a side surface of the first wiring of the first metal layer, and
wherein an upper surface of the third portion is coplanar with an upper surface of the first wiring of the first metal layer.

4. The semiconductor chip as claimed in claim 3, wherein the first via and the first wiring have an integrated structure.

5. The semiconductor chip as claimed in claim 2,
wherein the first heat-dissipation film further comprises a fourth portion extending along an upper surface of the first wiring, and
wherein the semiconductor chip further comprises:
a heat-dissipation insulation film overlapping the fourth portion in a second direction perpendicular to the first direction.

6. The semiconductor chip as claimed in claim 2, wherein the first heat-dissipation structure further comprises a heat-dissipation insulation film overlapping the second portion in a second direction perpendicular to the first direction.

7. The semiconductor chip as claimed in claim 6, wherein a thickness in the first direction of the second portion and a thickness in the first direction of the heat-dissipation insulation film are identical.

8. The semiconductor chip as claimed in claim 6,
wherein the first wiring structure further comprises a second wiring spaced apart from the first wiring in the second direction, and
wherein the heat-dissipation insulation film is located between the first wiring and the second wiring.

9. The semiconductor chip as claimed in claim 6,
wherein the 2D material constituting the first heat-dissipation structure comprises graphene, and
wherein the heat-dissipation insulation film comprises graphene oxide.

10. The semiconductor chip as claimed in claim 1, further comprising:
a second wiring structure on the second surface of the device layer; and
a support substrate on the first wiring structure, wherein the second wiring structure comprises:
a second via layer comprising a second via;
a second metal layer comprising a second wiring, the second metal layer being disposed on the second via layer; and
a second heat-dissipation structure on at least a portion of the second via or the second wiring.

11. The semiconductor chip as claimed in claim 1, further comprising:
a through electrode extending in the first direction and overlapping the device layer in a second direction perpendicular to the first direction;
a through heat-dissipation film extending along a bottom surface and a side surface of the through electrode; and
a surface heat-dissipation film connected to the through heat-dissipation film and extending in the second direction.

12. The semiconductor chip as claimed in claim 11, wherein the through heat-dissipation film is in contact with the first wiring structure.

13. A chip stacked structure, comprising:
a first semiconductor chip comprising a first substrate, a first device layer on the first substrate, and a first front side wiring structure on a front surface of the first device layer;
a second semiconductor chip comprising a second substrate, a second device layer on the second substrate, and a second front side wiring structure on a front surface of the second device layer, the second semiconductor chip being stacked on the first semiconductor chip;
a through electrode penetrating at least a portion of the first semiconductor chip; and
a through heat-dissipation film surrounding at least a portion of the through electrode,
wherein the first front side wiring structure comprises:
a first front side via layer comprising a first front side via, the first front side via layer being disposed on the first device layer,
a first front side metal layer comprising a first front side wiring, the first front side metal layer being disposed on the first front side via layer, and
a first front side heat-dissipation structure comprising a first portion surrounding a bottom surface and a side surface of the first front side via, and
wherein the second front side wiring structure comprises:
a second front side via layer comprising a second front side via, the second front side via layer being disposed on the second device layer,
a second front side metal layer comprising a second front side wiring, the second front side metal layer being disposed on the second front side via layer, and
a second front side heat-dissipation structure comprising a first portion surrounding a bottom surface and a side surface of the second front side via.

14. The chip stacked structure as claimed in claim 13,
wherein the first semiconductor chip further comprises a first back side wiring structure on a back surface of the first device layer and a first support substrate on the first front side wiring structure,
wherein the through electrode penetrates the first support substrate, and
wherein the through heat-dissipation film contacts the first back side wiring structure.

15. The chip stacked structure as claimed in claim 14, wherein the first back side wiring structure comprises:
a first back side via layer comprising a first back side via, the first back side via layer being disposed on the first device layer;
a first back side metal layer comprising a first back side wiring, the first back side metal layer being disposed on the first back side via layer; and
a first back side heat-dissipation structure comprising a first portion surrounding a bottom surface and a side surface of the first back side via.

16. The chip stacked structure as claimed in claim 15,
wherein the second semiconductor chip further comprises a second back side wiring structure on a back surface of the second device layer and a second support substrate on the second front side wiring structure, and
wherein the second back side wiring structure comprises:
a second back side via layer comprising a second back side via, the second back side via layer being disposed on the second device layer;
a second back side wiring layer comprising a second back side wiring, the second back side wiring layer being disposed on the second back side via layer; and
a second back side heat-dissipation structure comprising a first portion surrounding a bottom surface and a side surface of the second back side via.

17. The chip stacked structure as claimed in claim 13, wherein the first semiconductor chip further comprises a surface heat-dissipation film disposed on the first substrate.

18. The chip stacked structure as claimed in claim 17, further comprising:
a first surface insulation film disposed between the through heat-dissipation film and the surface heat-dissipation film;
a pad disposed in the surface heat-dissipation film on the first substrate;
a second surface insulation film disposed in the surface heat-dissipation film on the first substrate and surrounding the pad;
a first connection terminal disposed on the pad and connecting the first semiconductor chip and the second semiconductor chip; and
a second connection terminal disposed on the through electrode and connecting the first semiconductor chip and the second semiconductor chip.

19. The chip stacked structure as claimed in claim 18, wherein the first surface insulation film and the second surface insulation film comprise graphene oxide.

20. A semiconductor package, comprising:
a package substrate; and
a chip stacked structure disposed on the package substrate,
wherein the chip stacked structure comprises:
a first semiconductor chip comprising a first device layer and a first front side wiring structure on a front surface of the first device layer;
a second semiconductor chip comprising a second device layer and a second front side wiring structure on a front surface of the second device layer, the second semiconductor chip being stacked on the first semiconductor chip;
a through electrode penetrating at least a portion of the first semiconductor chip; and
a through heat-dissipation film surrounding at least a portion of the through electrode,
wherein the first front side wiring structure comprises:
a first front side via layer comprising a first front side via;
a first front side metal layer comprising a first front side wiring, the first front side metal layer being disposed on the first front side via layer; and
a first front side heat-dissipation structure comprising a first portion surrounding a bottom surface and a side surface of the first front side via, and
wherein the second front side wiring structure comprises:
a second front side via layer comprising a second front side via;
a second front side metal layer comprising a second front side wiring, the second front side metal layer being disposed on the second front side via layer; and
a second front side heat-dissipation structure comprising a first portion surrounding a bottom surface and a side surface of the second front side via, and
wherein each of the through heat-dissipation film, the first front side heat-dissipation structure, and the second front side heat-dissipation structure comprise a 2D material.
